(19) United States
(12) Patent Application Publication
(10) Pub. No.: US 2025/0287717 A1
(43) Pub. Date: Sep. 11, 2025

(54) IMAGE SENSOR DEVICE AND SEMICONDUCTOR STRUCTURE

(71) Applicant: Taiwan Semiconductor Manufacturing Company, Ltd., Hsinchu (TW)

(72) Inventors: Min-Feng Kao, Chiayi City (TW); Hsing-Chih Lin, Tainan City (TW); Jen-Cheng Liu, Hsin-Chu City (TW); Dun-Nian Yaung, Taipei City (TW)

(73) Assignee: Taiwan Semiconductor Manufacturing Company, Ltd., Hsinchu (TW)

(21) Appl. No.: 18/596,667

(22) Filed: Mar. 6, 2024

(51) Int. Cl. H01L 27/146

(52) U.S. Cl. CPC H10F 39/811; H10F 39/182

(57) ABSTRACT

An image sensor device includes a first semiconductor structure and a second semiconductor structure bonding with the first semiconductor structure. The first semiconductor structure includes a first semiconductor substrate and logic devices. The logic devices are disposed on the first semiconductor substrate. A through-substrate via is penetrating through the first semiconductor substrate and located between two of the logic devices. A second semiconductor structure includes a second semiconductor substrate and image sensors. The image sensors are disposed in a pixel area of the second semiconductor substrate. At least one of the image sensors is electrically to at least one of the two of the logic devices.

### BACKGROUND

The semiconductor integrated circuit (IC) industry has witnessed an exponential surge in growth. This growth has been fueled by technological advancements in IC materials and design, leading to the production of successive generations of ICs. Each generation is characterized by smaller, more intricate circuits than its predecessor. As ICs have evolved, there has been a general increase in functional density (i.e., the number of interconnected devices per chip area), while the geometry size (i.e., the smallest component or line that can be fabricated) has decreased. This miniaturization process typically yields benefits such as enhanced production efficiency and reduced costs. However, it also escalates the complexity of IC processing and manufacturing.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic cross-sectional view of an embodiment image sensor device in accordance with various embodiments.

FIG. 1B is a schematic top view of a first semiconductor structure in accordance with various embodiments.

FIG. 1C is a schematic top view of a second semiconductor structure in accordance with various embodiments.

FIGS. 2A to 2J are schematic cross-sectional views of a fabrication method of an embodiment image sensor device in accordance with various embodiments.

FIG. 3 is a schematic cross-sectional view of an embodiment first semiconductor structure in accordance with various embodiments.

FIGS. 4A to 4H are schematic cross-sectional views of a fabrication method of an embodiment image sensor device in accordance with various embodiments.

FIGS. 5A to 5N are schematic cross-sectional views of a fabrication method of an embodiment image sensor device in accordance with various embodiments.

FIG. 6 is a schematic cross-sectional view of an embodiment first semiconductor structure in accordance with various embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the structure in use or operation in addition to the orientation depicted in the figures. The apparatus may be otherwise oriented (rotated 90 degrees or at other orientations) and the spatially relative descriptors used herein may likewise be interpreted accordingly.

In some integrated circuits, the front side of a substrate of a wafer includes various doped regions. These doped regions may work with the gate stack structures formed over the substrate to function as transistors. An interlayer dielectric (ILD) layer may be disposed above the front side of the substrate and cover the gate stack structures. The ILD layer contains various contact vias that connect to the transistors, such as gate contact vias and source/drain contact vias. An interconnect structure may be disposed above the ILD layer and include multiple metallization layers and inter-metal dielectric (IMD) layers situated between the metallization layers. The metallization layers in the interconnect structure may be referred to as M1, M2, M3 . . . Mn layers, depending on their level. The metallization layer closest to the ILD layer may also be referred to as the M1 layer, while the metallization layer furthest from the ILD layer may also be referred to as the Mn layer.

In some integrated circuits, a backside circuit structure is formed on the backside of the substrate, and a through-substrate via (TSV), also known as a backside through-substrate via (BTSV) in some cases, is used to connect the backside circuit structure with the interconnect structure over the front side of the substrate. In certain integrated circuits, the TSV extends from the backside of the substrate to the interconnect structure, potentially reaching as far as the M1 layer. This necessitates the TSV to traverse entirely through the ILD layer that lies between the interconnect structure and the substrate. As a consequence, the TSV is required to possess a significantly larger depth and area.

In some embodiments disclosed here, the depth and size of the TSV are reduced, thereby providing greater design flexibility of the integrated circuits. For instance, in an image sensor device, to avoid any negative impact on resolution, the TSV is typically positioned around the periphery of the pixel area of the image sensor device, ensuring that it does not overlap with the radiation sensing elements in the pixel area. However, if the size of the TSV can be reduced, the TSV may overlap with the pixel area without affecting the resolution of the image sensor device. This not only shortens the signal path from the radiation sensing elements to the TSV but also reduces the size of the image sensor device. By shortening the signal path between the radiation sensing element and the TSV, not only can the resistance-capacitance delay (RC delay) of the signal be reduced, but it also minimizes the issue of signal crosstalk during transmission.

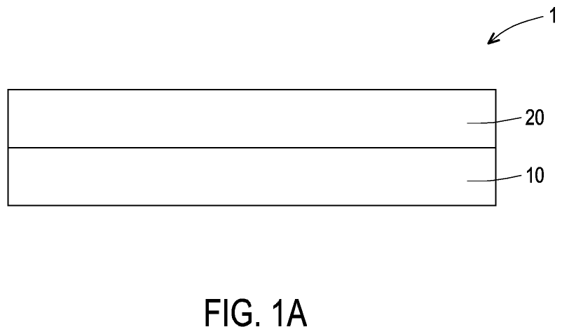

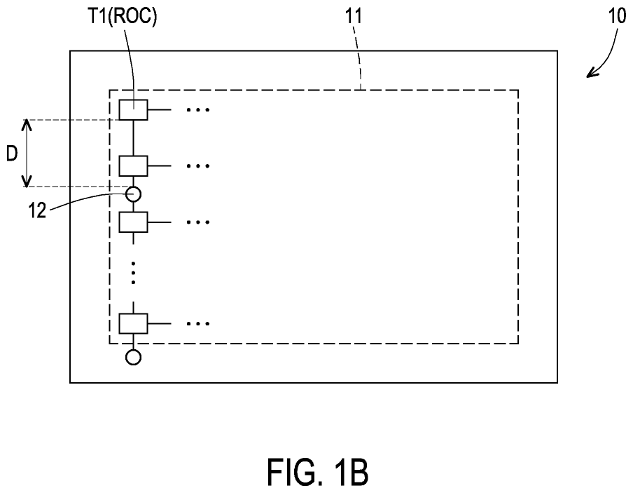

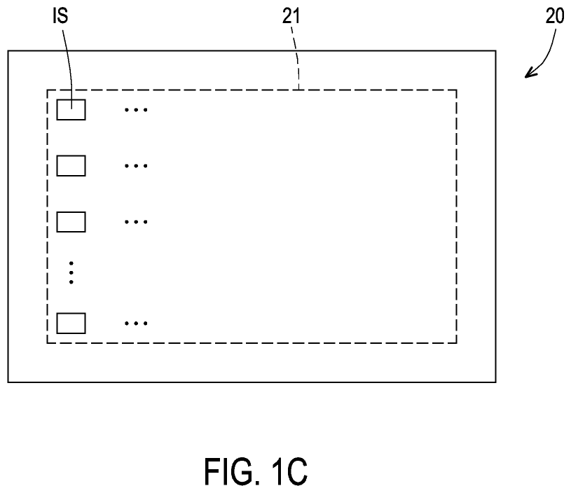

FIG. 1A is a schematic cross-sectional view of an embodiment image sensor device 1 in accordance with various embodiments. The image sensor device 1 includes a first semiconductor structure 10 and a second semiconductor structure 20. The first semiconductor structure 10 and the second semiconductor structure 20 can either be dies or wafers. Alternatively, one of them could be a die while the other is a wafer. In some embodiments, both the first semiconductor structure 10 and the second semiconductor structure 20 can be System-on-Chip (SoC) dies or other appropriate semiconductor dies.

Referring to FIGS. 1A and 1B, the first semiconductor structure 10, alternatively referred to as a logic wafer (or logic die), includes a variety of components such as read-out circuits, decoders, registers, multiplexers/de-multiplexers, amplifiers, reference pixels, and so on. In some instances, the first semiconductor structure 10 may include an application-specific integrated circuit (ASIC).

The first semiconductor structure 10 comprises multiple transistors, denoted as T1. These transistors are located in an active region 11 of the first semiconductor structure 10 and are arranged in multiple rows and columns. For instance, the first semiconductor structure 10 includes read-out circuits ROC, and each read-out circuit ROC incorporates several logic devices including the transistor T1. In FIG. 1B, the transistors T1 in the first semiconductor structure 10 are shown, while other types of transistors are not depicted. For example, the transistors T1 may be logic devices, such as reset transistors, source follower transistors, or row selector transistors.

In some implementations, the read-out circuits within the same row are electrically connected to each other, while the read-out circuits in the same column are electrically connected to multiple through-substrate vias (TSVs) 12. For example, the transistors T1 in one column correspond to multiple TSVs 12. These TSVs 12 may be located either within or outside the active region 11. At least one of the TSVs 12 disposed within the active region 11 is located between two adjacent transistors T1. In contrast to devices where the TSVs 12 are positioned outside the active region 11, situating the TSVs 12 between the transistors T1 can effectively shorten the signal transmission path between the transistors T1 and their corresponding TSVs 12. This arrangement not only reduces the Resistance-Capacitance (RC) delay of the signal but also improves the frame rate of the image sensor device 1. In some embodiments, the distance D between the TSV 12 and the farthest one of the corresponding transistors T1 that is electrically connected to the TSV 12 ranges from 1000 micrometers to 9000 micrometers. In some embodiments, signal lines between the transistors T1 and the corresponding TSVs 12 can be referred to as bit lines.

Referring to FIGS. 1A and 1C, the second semiconductor structure 20, alternatively referred to as a sensor wafer (or sensor die), includes image sensors IS. The image sensors IS are disposed in a pixel area 21 and are arranged in multiple rows and columns. In some embodiments, the image sensors IS includes a radiation-sensing region, a transfer gate, and a charge-to-voltage conversion region. The radiation-sensing region is configured to receive and collect a radiation wave that enter from the back side of the second semiconductor structure 20. Specifically, the radiation-sensing region receives photons of the radiation wave and converts the photons into an electrical signal and charges. The radiation-sensing region is realized as a photodiode, a pinned photodiode, or a p-n junction disposed within the semiconductor substrate of the second semiconductor structure 20, which is able to generate a signal related to the intensity or brightness of light that strikes the radiation-sensing region. The radiation wave stimulates the radiation-sensing region, leading to the generation of electron-hole pairs in a depletion region of the photodiode. Furthermore, the radiation-sensing region has the capability to sense or detect radiation waves at specific wavelengths, which may be associated with lights of various colors.

The transfer gate is interposed between the radiation-sensing region and the charge-to-voltage conversion region. The transfer gate is implemented as a control gate having a metal gate structure or a polysilicon structure. The electrons or charges in the radiation-sensing region transfer to the charge-to-voltage conversion region under the control of the transfer gate. Further, the charge-to-voltage conversion region serves as a region configured for transforming the electrons or charges into a corresponding voltage.

The second semiconductor structure 20 is bonded to the first semiconductor structure 10. The bonding process can be accomplished through various methods, including but not limited to, die-to-die assemblies, wafer-to-wafer assemblies, die-to-substrate assemblies, and die-to-wafer assemblies. As a result, a three-dimensional (3D) structure is formed. The bonding process can be accomplished through methods such as fusion bonding, hybrid bonding, or other suitable techniques. In some embodiments, the read-out circuits in the first semiconductor structure 10 are electrically connected with the radiation sensing elements SE of the second semiconductor structure 20. The pixel area 21 of the second semiconductor structure 20 is at least partially overlapping with the active region 11 of the first semiconductor structure 10. In some embodiments, at least a portion of the TSVs 12 and the transistors in the first semiconductor structure 10 are overlapping with the pixel area 21 of the second semiconductor structure 20.

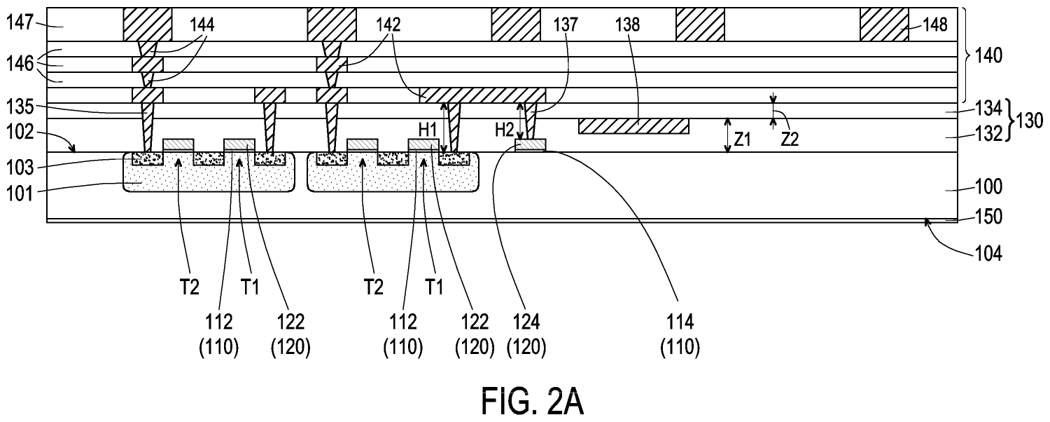

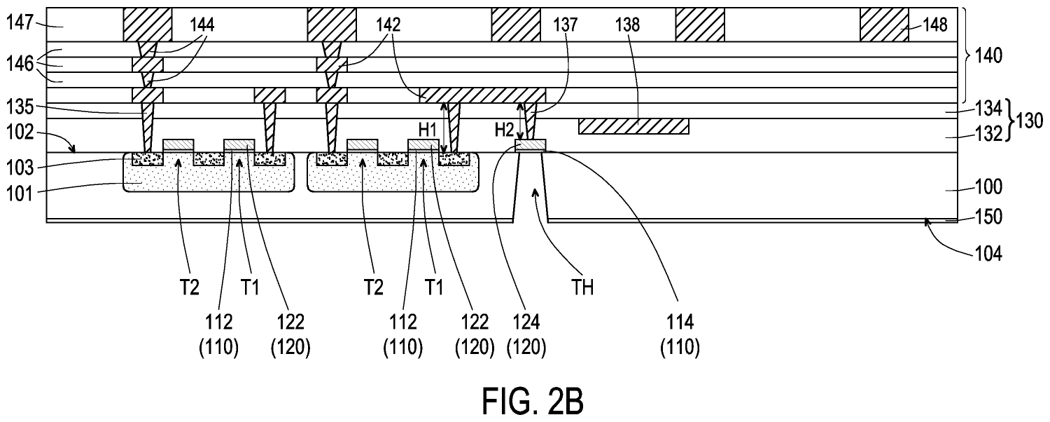

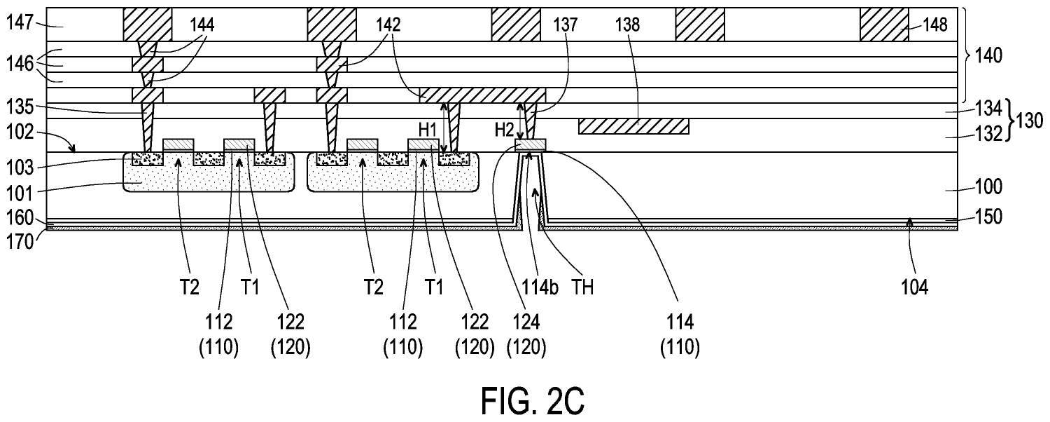

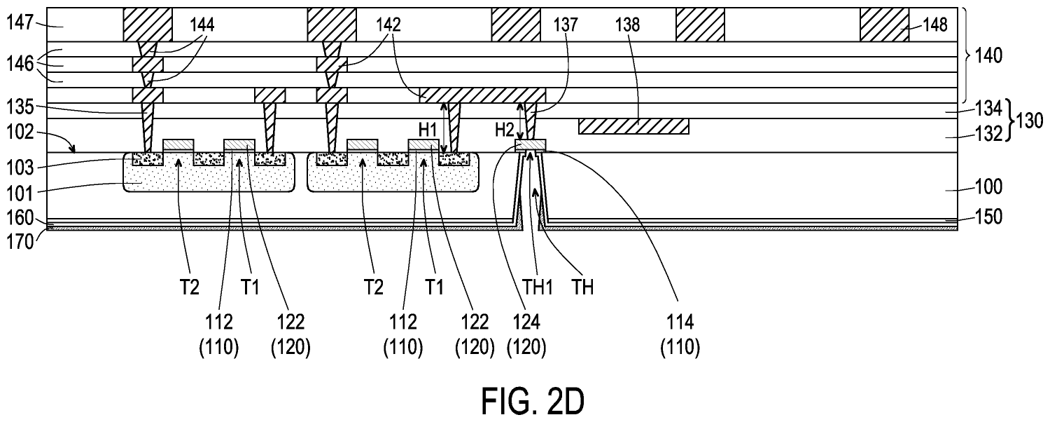

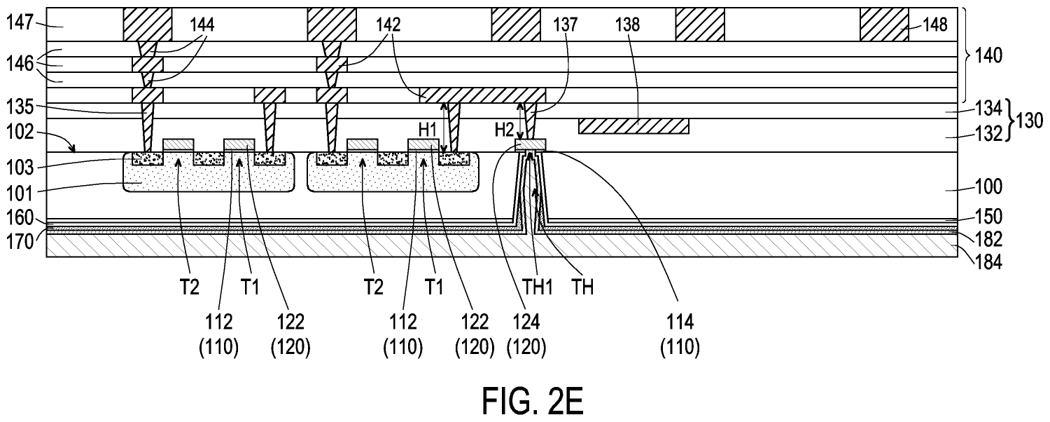

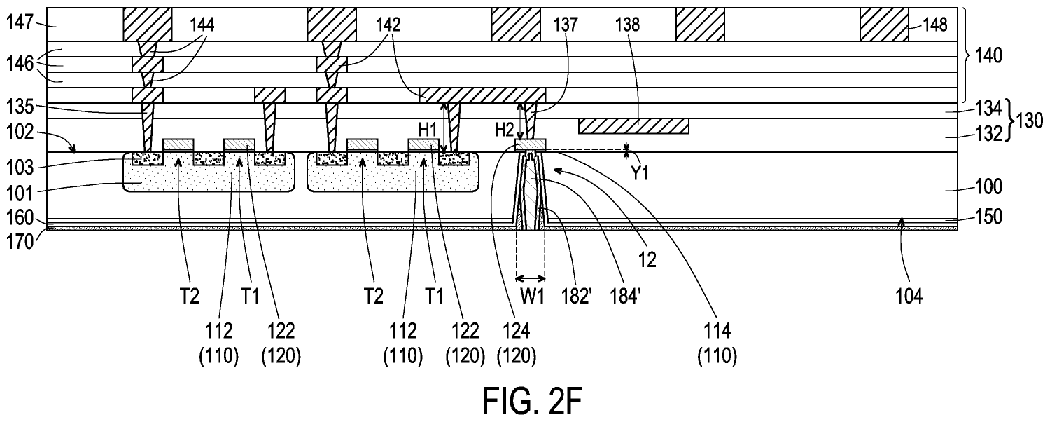

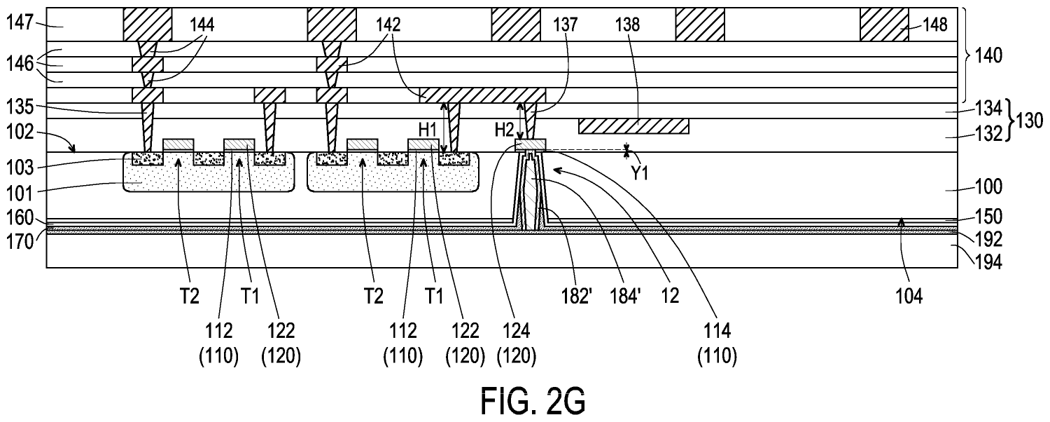

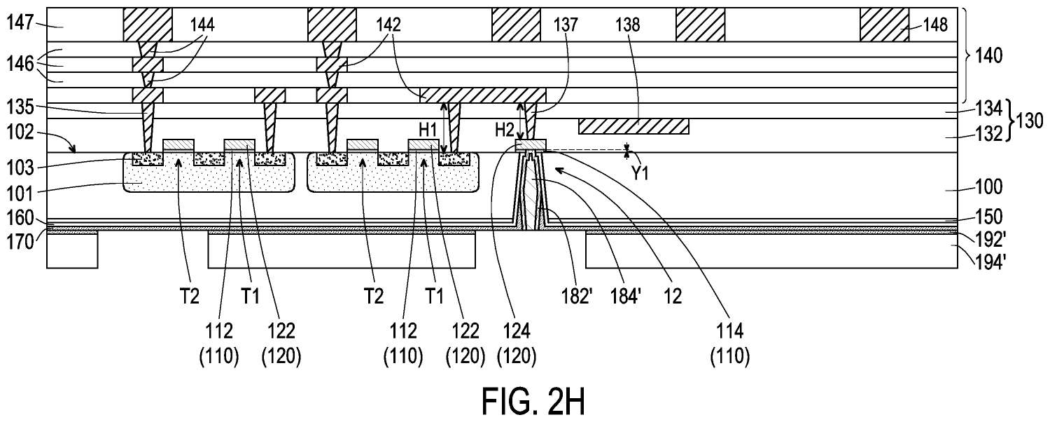

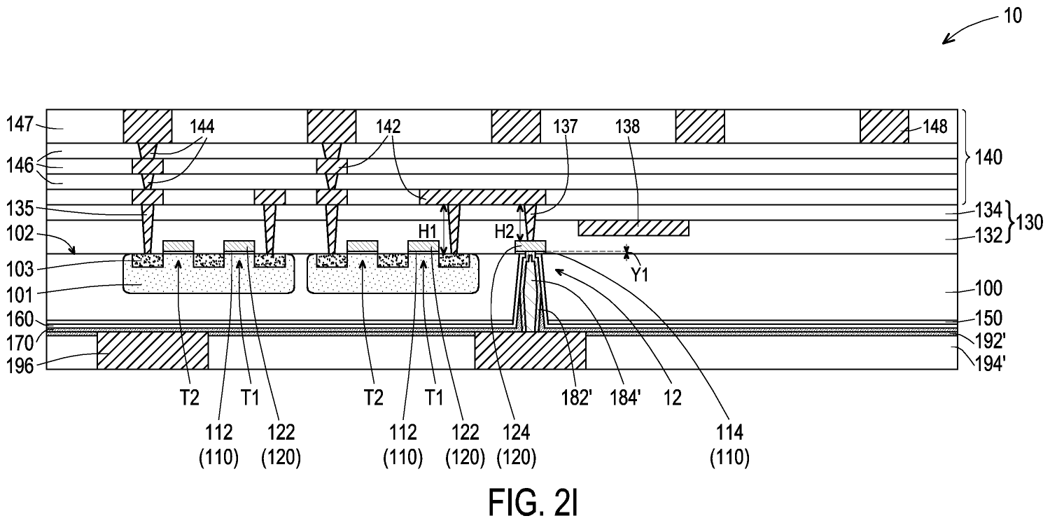

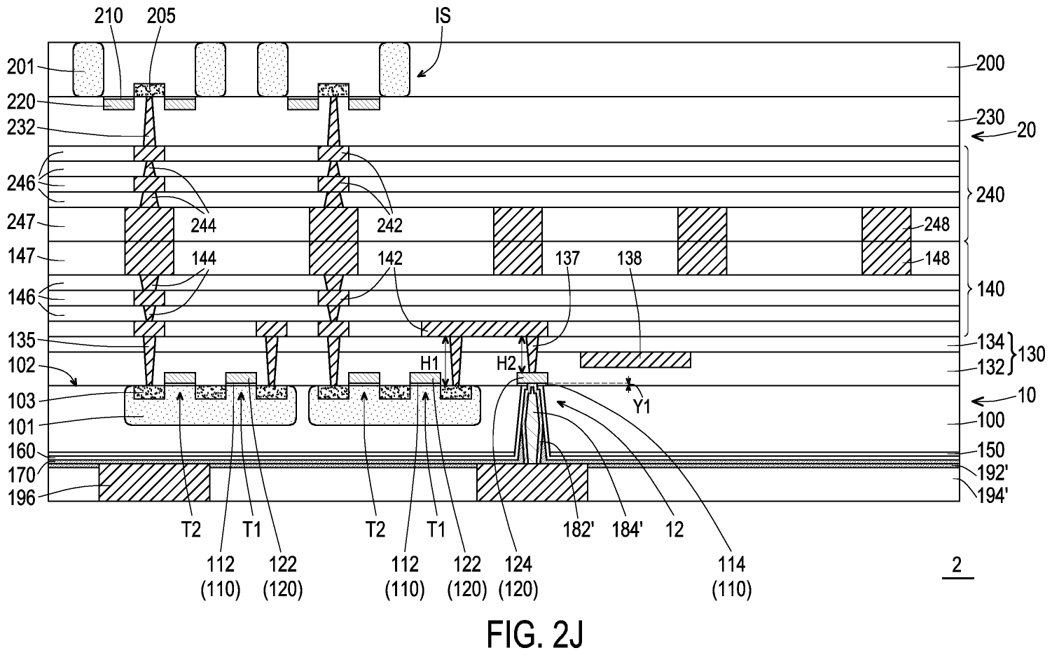

FIGS. 2A to 2J are schematic cross-sectional views of a fabrication method of an embodiment image sensor device 2 in accordance with various embodiments. Referring to FIG. 2A, a first semiconductor substrate 100 is provided. The first semiconductor substrate 100 may comprise a silicon substrate, which may be doped with either a P-type dopant, such as boron, or an N-type dopant, such as phosphorous or arsenic. In addition to silicon, the first semiconductor substrate 100 may also incorporate other elementary semiconductors like germanium. Optionally, it may include a compound semiconductor or an alloy semiconductor. Moreover, the first semiconductor substrate 100 may feature an epitaxial layer (also known as an epi layer), may be strained to enhance performance, and may include a silicon-on-insulator (SOI) structure.

The read-out circuits are formed on the front side 102 of the first semiconductor substrate 100. In some embodiments, the read-out circuits are arranged in rows and columns, and each read-out circuit includes logic devices, such as a transistor T1 and a transistor T2. In some embodiments, the transistor T1 is a row selector transistor, and the transistor T2 is a source follower transistor. In some embodiments, each read-out circuit further includes a reset transistor (not shown) electrically connected with the transistor T2.

The channel features 101 and the source/drain features 103 of the transistors T1 and the transistors T2 may be formed by performing a plurality of ion implantation processes on the first semiconductor substrate 100. The ion implantation processes may include multiple implant steps and may use different types of dopants, implant dosages, and implantation energies. The ion implantation processes may also use different masks that have different patterns and opening sizes.

A gate insulation layer 110 and a gate electrode layer 120 are formed over the front side 102 of the first semiconductor substrate 100. The gate insulation layer 110 includes gate insulators 112 and an insulation structure 114. In some embodiments, the gate insulators 112 and the insulation structure 114 are separated from each other, but the disclosure is not limited thereto. In other embodiments, the gate insulators 112 and the insulation structure 114 are connected with each other. In some embodiments, the gate insulation layer 110 comprises silicon oxide. In some embodiments, the gate insulation layer 110 comprises a high-k dielectric material. As used herein, the term “high-k dielectric” refers to the material having a dielectric constant, κ, greater than or equal to about 3.9, which is the k value of SiO₂. The material of the high-k dielectric layer may be any suitable material. Examples of the material of the high-k dielectric layer include but are not limited to Al₂O₃, HfO₂, ZrO₂, La₂O₃, TiO₂, SrTiO₃, LaAlO₃, Y₂O₃, Al₂OxNy, HfOxNy, ZrOxNy, La₂OxNy, TiOxNy, SrTiOxNy, LaAlOxNy, Y₂OxNy, SiON, SiNx, a silicate thereof, and an alloy thereof. Each value of x is independently from 0.5 to 3, and each value of y is independently from 0 to 2. In some embodiments, the thickness of the gate insulation layer 110 is in a range between approximately 10 Angstroms to approximately 1000 Angstroms.

The gate electrode layer 120 includes gate electrodes 122 and a conductive pad 124. The gate insulators 112 are located between the gate electrodes 122 and the first semiconductor substrate 100, and the insulation structure 114 is located between the conductive pad 124 and the first semiconductor substrate 100. In some embodiments, the sidewalls of the gate electrodes 122 are aligned with the sidewalls of the gate insulators 112, and the sidewalls of the conductive pad 124 are aligned with the sidewalls of the insulation structure 114, but the disclosure is not limited thereto.

In some embodiments, the gate electrode layer 120 is made of polysilicon, metal (such as copper, tungsten, or the like) of other conductive materials. In some embodiments, the thickness of the gate electrode layer 120 is in a range between approximately 500 Angstroms to approximately 3000 Angstroms.

An interlayer dielectric (ILD) structure 130 is disposed over the transistors T1 and the transistors T2. In some embodiments, the ILD structure 130 includes two or more dielectric layers. For example, the ILD structure 130 includes a first ILD layer 132 and a second ILD layer 134. The first ILD layer 132 is disposed over the transistors T1 and the transistors T2. The second ILD layer 134 is disposed over the first ILD layer 132.

In some embodiments, the gate electrodes 122 and the conductive pad 124 are embedded in the first ILD layer 132 and located between the first ILD layer 132 and the first semiconductor substrate 100. In some embodiments, the first ILD layer 132 may include silicon oxide, SiOC, SiOCN or SiCN or other low-k materials, or porous materials, or any other suitable dielectric material. In some embodiments, the first ILD layer 132 may include low-k dielectric materials having κ values, for example, lower than about 3.9 or even 2.0. The first ILD layer 132 can be formed by LPCVD (low pressure chemical vapor deposition), plasma-CVD, flowable CVD or other suitable film forming methods.

In some embodiments, formation of the first ILD layer 132 is followed by a damascene process to form openings within the first ILD layer 132 and fill those openings with a metal material (e.g., copper, aluminum, tungsten, and so on). A planarization process can be then performed to remove excess metal material to form an interlayer conductive layer 138 within the first ILD layer 132. In some embodiments, the interlayer conductive layer 138 interconnect structure may be referred to as M0 layer. In some embodiments, the thickness of the interlayer conductive layer 138 is in a range between approximately 50 Angstroms to approximately 3000 Angstroms.

The second ILD layer 134 is disposed over the first ILD layer 132 and covers the interlayer conductive layer 138. That is, the interlayer conductive layer 138 is embedded in the ILD structure 130 and located between the first ILD layer 132 and the second ILD layer 134. In some embodiments, the second ILD layer 134 may include silicon oxide, SiOC, SiOCN or SiCN or other low-k materials, or porous materials, or any other suitable dielectric material. In some embodiments, the second ILD layer 134 may include low-k dielectric materials having k values, for example, lower than about 4.0 or even 2.0. The second ILD layer 134 can be formed by LPCVD (low pressure chemical vapor deposition), plasma-CVD, flowable CVD or other suitable film forming methods.

In some embodiments, the first ILD layer 132 has a thickness Z1 in a range between approximately 10 Angstroms to approximately 3000 Angstroms. In some embodiments, the second ILD layer 134 has a thickness Z2 in a range between approximately 10 Angstroms to approximately 3000 Angstroms.

The source/drain contact vias 135 and the conductive via 137 are embedded within the ILD structure 130. In some embodiments, after forming the second ILD layer 134, one or more etching processes are performed to create multiple openings in the ILD structure 130. Some of these openings expose parts of the source/drain features 103, while others expose the conductive pad 124. A metal material (e.g., copper, aluminum, tungsten, and so on) is then filled into these openings. Subsequently, a planarization process is performed to remove excess metal material, thereby forming the source/drain contact vias 135 and the conductive via 137 within the ILD structure 130.

In some embodiments, in addition to forming the source/drain contact vias 135 and the conductive via 137 within the ILD structure 130, gate contact vias (not shown) are also formed on the gate electrodes 122 within the ILD structure 130.

The source/drain contact vias 135 are extending from a top surface of the ILD structure 130 to corresponding source/drain features 103 of the transistors T1, T2, and electrically connected with the corresponding source/drain features 103 of the transistors T1, T2. In some embodiments, the source/drain feature 103, located between one transistor T1 and an adjacent transistor T2, is not connected with any source/drain contact via 135, but the disclosure is not limited thereto. In some embodiments, the source/drain contact vias 135 are penetrating through the first ILD layer 132 and the second ILD layer 134.

The conductive via 137 is extending from the top surface of the ILD structure 130 into the ILD structure 130. The conductive via 137 is disposed over and electrically connected with the conductive pad 124. In some embodiments, the conductive via 137 is penetrating through the second ILD layer 134, but not penetrating through the first ILD layer 132. In some embodiments, a height H1 of the source/drain contact vias 135 is greater than a height H2 of the conductive via 137.

An interconnect structure 140 is disposed over the ILD structure 130 and electrically connected with the conductive via 137 and the source/drain contact vias 135. In certain embodiments, referring to both FIGS. 1B and 2A, multiple transistors T1 are arranged in the same column and are segmented into several groups. Each group contains one or more transistors T1, and the transistors T1 within each group are electrically interconnected through the interconnect structure 140. However, the source/drain features 103 of the transistors T1 in different groups are not electrically interconnected to each other through the interconnect structure 140. In some embodiments, the transistors T1 in the same group are electrically connected to the same conductive via 137 through the interconnect structure 140. For example, one of the source/drain features 103 of a transistor T1 is electrically connected to the corresponding source/drain feature 103 of an adjacent transistor T1 through the interconnect structure 140.

In this embodiment, the source/drain features 103 of the transistors T1 are electrically connected to the conductive via 137, but this disclosure is not limited to this. In other embodiments, the gate electrodes 122 of the transistors T1 or the transistors T2 are electrically connected to the conductive via 137.

The interconnect structure 140 may include a plurality of metallization layers 142 and a plurality of metal vias 144. The number of metallization layers 142 may vary according to design specifications of the semiconductor device. The metallization layers 142 closest to the ILD structure 130 can be referred to as the M1 layer. The M1 layer is in contact with the source/drain contact vias 135 and the conductive via 137. The metallization layers 142 at different levels are electrically interconnected through metal vias 144. The metallization layers 142 and the metal vias 144 are located within the inter-metallization dielectric (IMD) layers 146.

In some embodiments, the IMD layers 146 may, for example, be or comprise an oxide (e.g., SiO₂), a low-k dielectric, an extreme low-k dielectric, or a combination of the aforementioned dielectric materials formed within a thickness of approximately 200 Angstroms to approximately 9000 Angstroms. As used herein, a low-k dielectric may be, for example, a dielectric with a dielectric constant κ lower than about 3.9 or even 2.0. In some embodiments, etch stop layers (not shown) are located between the adjacent IMD layers 146. The etch stop layers may, for example, be or comprise silicon carbide (SiC), silicon nitride (SiN), silicon oxynitride (SiON), silicon oxycarbide (SiOC), an oxide layer, or a combination of the aforementioned dielectric materials.

The topmost layer of the interconnect structure 140 includes bonding pads 148 and a bonding layer 147. Both the bonding pads 148 and the bonding layer 147 are used in the hybrid bonding process. Specifically, the bonding pads 148 are used for metal-to-metal bonding, while the bonding layer 147 is used for insulator-to-insulator (or dielectric-to-dielectric) bonding during the bonding process.

A buffer layer 150 is formed on the back side 104 of the first semiconductor substrate 100. In some embodiments, the buffer layer 150 comprises oxide (such as silicon oxide) or other dielectric materials. In certain embodiments, the buffer layer 150 is utilized to protect the back side 104 of the first semiconductor substrate 100 during subsequent chemical mechanical planarization (CMP) or etching processes.

Referring to FIG. 2B, a through hole TH is formed in the first semiconductor substrate 100 by a wet etching process, a dry etching process, or a combination thereof. In some embodiments, the through hole TH passes through both the buffer layer 150 and the first semiconductor substrate 100, stopping at the gate insulation layer 110. This arrangement helps to prevent the etching process from damaging the conductive pad 124. If the etching process does damage the conductive pad 124, the ions from the conductive pad 124 could potentially contaminate the first semiconductor substrate 100. This is especially the case during the formation of the through hole TH using a dry etching process. If the dry etching process were to penetrate the gate insulation layer 110, it could potentially result in damage to the conductive pad 124.

However, this disclosure is not limited to having the through hole TH stop at the gate insulation layer 110. In some embodiments, by controlling the etching process, the through hole TH can pass through the gate insulation layer 110 and stop at the conductive pad 124. The aforementioned etching process can be a combination of the wet etching process and the dry etching process.

Referring to FIG. 2C, a blanket dielectric layer 160 is formed over the back side 104 of the first semiconductor substrate 100. The blanket dielectric layer 160 is formed on the buffer layer 150 and in the through hole TH. The blanket dielectric layer 160 covers the sidewalls of the through hole TH and the gate insulation layer 110 exposed by the through hole TH. The blanket dielectric layer 160 is in contact with the gate insulation layer 110. In some embodiments, the through hole TH extends through the gate insulation layer 110, exposing the conductive pad 124. In such cases, the blanket dielectric layer 160 comes into contact with the conductive pad 124. In some embodiments, the blanket dielectric layer 160 includes oxides (such as silicon oxide) or other dielectric materials. In some embodiments, the methods for forming the blanket dielectric layer 160 include physical vapor deposition (PVD), chemical vapor deposition (CVD), atomic layer deposition (ALD), or the like.

A mask layer 170 is disposed above the blanket dielectric layer 160. The mask layer 170 is formed over the back side 104 of the first semiconductor substrate 100. In some embodiments, by adjusting the deposition rate of the mask layer 170, it is ensured that the mask layer 170 does not close the through hole TH. Therefore, there is no need to use a photomask process to pattern the mask layer 170. In some embodiments, the deposition rate of the mask layer 170 is greater than that of the blanket dielectric layer 160. In some embodiments, the material of the mask layer 170 includes nitrides (such as silicon nitride) or other dielectric materials.

In some embodiments, a part of the mask layer 170 is filled in the through hole TH, but does not completely cover the blanket dielectric layer 160 within the through hole TH. In other words, the part of the mask layer 170 is filled into the through hole TH and has an opening that exposes the blanket dielectric layer 160 in the through hole TH. The width of the opening in mask layer 170 is smaller than that of the through hole TH.

Referring to FIG. 2D, an etching process is performed on the blanket dielectric layer 160 and the gate insulation layer 110 to form a through hole TH1 passing through the blanket dielectric layer 160 and the gate insulation layer 110. In some embodiments, the width of the through hole TH is greater than that of the through hole TH1.

In some embodiments, the mask layer 170 is used as a mask to perform an etching process. This process etches the blanket dielectric layer 160 and the gate insulation layer 110 located at the bottom of the through hole TH, thereby exposing the conductive pad 124. In some embodiments, the blanket dielectric layer 160 extends through the gate insulation layer 110 and contacts the conductive pad 124. In such cases, the aforementioned etching process only needs to etch the blanket dielectric layer 160 in the through hole TH to expose the conductive pad 124.

Referring to FIG. 2E, a barrier material layer 182 is formed over the mask layer 170 and fills into the through holes TH, TH1. In some embodiments, the barrier material layer 182 comes into contact with the blanket dielectric layer 160 within the through holes TH, and contacts the sidewalls of the gate insulation layer 110 within the through holes TH1.

A metal layer 184 is then deposited over the barrier material layer 182 and into the through hole TH (or the through holes TH, TH1). In some embodiments, the metal layer 184 may consist of copper or copper alloys, and the barrier material layer 182 may include a nitride (such as titanium nitride, tantalum nitride, or the like) to prevent, for example, the diffusion of copper ions. In other embodiments, the metal layer 184 may comprise other metal materials (such as tungsten), and the barrier material layer 182 can be omitted.

Referring to FIG. 2F, a CMP process is performed to remove excess materials from the metal layer 184 and the barrier layer 182, thereby forming the conductive plug 184′ and the barrier layer 182′. The conductive plug 184′ is embedded within the first semiconductor substrate 100, with the blanket dielectric layer 160 and the barrier layer 182′ located between the conductive plug 184′ and the first semiconductor sub strate 100. The barrier layer 182′ surrounds the conductive plug 184′. In some embodiments, a portion of the mask layer 170 is laterally located between the barrier layer 182′ and the blanket dielectric layer 160.

In this embodiment, the CMP process stops at the mask layer 170. The portions of the metal layer 184 and the barrier material layer 182 that extend beyond the mask layer 170 are removed during the CMP process. However, this disclosure is not limited thereto. In other embodiments, the CMP process stops at the blanket dielectric layer 160 or the buffer layer 150, and any materials extending beyond the blanket dielectric layer 160 or the buffer layer 150 are removed during the CMP process.

In this embodiment, a TSV 12 includes the barrier layer 182′ and the conductive plug 184′, extending from the back side 104 of the first semiconductor substrate 100 to beyond the front side 102 of the first semiconductor substrate 100. In this instance, the TSV 12 penetrates through the insulation structure 114 of the gate insulation layer 110 and is in contact with the conductive pad 124. In some embodiments, a depth Y1 of the TSV 12 beyond the front side 102 of the first semiconductor substrate 100 is less than or equal to a thickness Z1 of the first ILD layer 132. In some instances, the depth Y1 is approximately equal to the thickness of the gate insulation layer 110.

The conductive pad 124 is located between the TSV 12 and the conductive via 137. The TSV 12 is electrically connected with the conductive via 137 through the conductive pad 124, and further electrically connected with the transistor T1 through the interconnect structure 140 and the source/drain contact via 135.

In this embodiment, since the TSV 12 does not extend through the ILD structure 130, the resulting TSV 12 may have a smaller depth, for example, ranging from 0.1 micrometers to 3 micrometers. Due to the reduction in the depth of the TSV 12, the TSV 12 may have a smaller critical dimension (CD) W1, for instance, ranging from 0.05 micrometers to 3 micrometers.

Then, a backside circuit is formed over the back side 104 of the first semiconductor substrate 100, as shown in FIGS. 2G to 2I. Referring to FIG. 2G, a nitride layer 192 is formed over the back side 104 and covers the TSV 12. In this embodiment, since the CMP process of forming the TSV 12 stops on the mask layer 170, the nitride layer 192 is formed on the mask layer 170. In other embodiments, the aforementioned CMP process stops on the blanket dielectric layer 160 or the buffer layer 150, and the nitride layer 192 is formed on the blanket dielectric layer 160 or the buffer layer 150. In some embodiments, the nitride layer 192 includes silicon nitride or other suitable materials. A dielectric material layer 194 is formed over the nitride layer 192. In some embodiments, the dielectric material layer 194 includes silicon oxide or other suitable materials.

Referring to FIG. 2H, a patterning process is performed on the dielectric material layer 194 and the nitride layer 192 to form a dielectric layer 194′ and a nitride layer 192′ with openings and/or trenches. The TSV 12 is exposed after the patterning process.

Referring to FIG. 2I, a metal layer 196 is formed in the openings and/or trenches of the dielectric layer 194′ and the nitride layer 192′. In some embodiments, a metal material is first deposited over the dielectric layer 194′, followed by a CMP process to remove the metal material exceeding the dielectric layer 194′, leaving behind the metal layer 196.

In this embodiment, the backside circuit includes the metal layer 196, but this disclosure is not limited to this. The backside circuit may also include multiple layers of metal layers. Furthermore, in some embodiments, the backside circuit may also include bonding pads and/or a bonding layer for bonding with other devices.

Referring to FIG. 2J, a second semiconductor structure 20 is bonding with the first semiconductor structure 10 (as shown in FIG. 21) by hybrid bonding process.

The second semiconductor structure 20 includes a second semiconductor substrate 200, an ILD structure 230, and an interconnect structure 240.

The second semiconductor substrate 200 may comprise a silicon substrate, which may be doped with either a P-type dopant, such as boron, or an N-type dopant, such as phosphorous or arsenic. In addition to silicon, the second semiconductor substrate 200 may also incorporate other elementary semiconductors like germanium. Optionally, it may include a compound semiconductor or an alloy semiconductor. Moreover, the second semiconductor substrate 200 may feature an epitaxial layer (also known as an epi layer), may be strained to enhance performance, and may include a silicon-on-insulator (SOI) structure.

The image sensor IS includes a radiation-sensing region 201, a transfer gate 220, and a charge-to-voltage conversion region 205. The radiation-sensing region 201 is located in the second semiconductor substrate 200, adjacent to the transfer gate 220. This region is designed to receive and accumulate radiation waves entering from the back side of the second semiconductor substrate 200. The radiation-sensing region 201, which can be a photodiode, a pinned photodiode, or a p-n junction located in the second semiconductor substrate 200, is capable of generating a signal that corresponds to the intensity or brightness of the light striking the radiation-sensing region 201.

The image sensors IS are arrayed in a pixel area of the second semiconductor substrate 20 and arranged in multiple rows and columns, as shown in FIG. 1C. In other words, the radiation-sensing region 201, the transfer gate 220, and the charge-to-voltage conversion region 205 are disposed in the pixel area.

The transfer gate 220 is located laterally adjacent to and coupled with the radiation-sensing region 201. The transfer gate 220 is located between the radiation-sensing region 201 and the charge-to-voltage conversion region 205. The transfer gate 220, which can be a control gate with a metal gate structure or a polysilicon structure, controls the transfer of electrons or charges from the radiation-sensing region 201 to the charge-to-voltage conversion region 205. Furthermore, the charge-to-voltage conversion region 205 functions as a region designed to convert the electrons or charges into a corresponding signal. The gate insulation layer 210 is located between the transfer gate 220 and the second semiconductor substrate 200.

The ILD structure 230 is disposed over the transfer gates 220. Gate contact vias 232 are embedded in the ILD structure 230 and electrically connected with the transfer gates 220.

The interconnect structure 240 is disposed over the ILD structure 230 and electrically connected with the gate contact vias 232. The interconnect structure 240 may include a plurality of metallization layers 242 and a plurality of metal vias 244. The number of metallization layers 242 may vary according to design specifications of the semiconductor device. The metallization layers 242 at different levels are electrically interconnected through metal vias 244. The metallization layers 242 and the metal vias 244 are located within the IMD layers 246.

The topmost layer of the interconnect structure 240 includes bonding pads 248 and a bonding layer 247. Both the bonding pads 248 and the bonding layer 247 are used in the hybrid bonding process. Specifically, the bonding pads 248 are bonded with the bonding pads 148, while the bonding layer 247 is bonded with the bonding layer 147 during the bonding process.

The image sensors IS are electrically connected to the transistors T1, T2 via the interconnect structures 140, 240. In some embodiments, reducing the distance between the TSV 12 and the transistor T1 may reduce the signal transmission path between the image sensor IS and the corresponding TSV 12, thereby improving the RC delay problem. In some embodiments, the TSV 12 is overlapping with the pixel area composed of the array of the image sensors IS. For example, the TSV 12 is overlapping with the second semiconductor substrate 200 between two adjacent image sensors IS or overlapping with the image sensor IS.

In some embodiments, the image sensor device 2 includes the second semiconductor structure 20 and the first semiconductor structure 10, but this disclosure is not limited thereto. In other embodiments, the image sensor device 2 further includes other semiconductor structures, such as ASIC, bonded to the back side of the first semiconductor structure 10. In some embodiments, optical elements such as color filters, lens, or other optical elements may be placed on the back side of the second semiconductor structure 20 facing away from the first semiconductor structure 10, but this disclosure is not limited thereto.

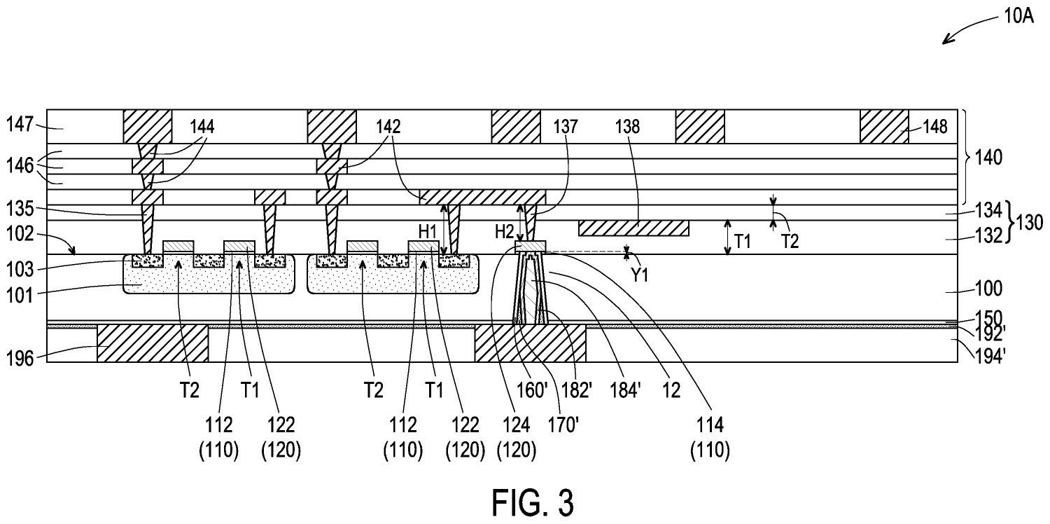

FIG. 3 is a schematic cross-sectional view of an embodiment first semiconductor structure 10A in accordance with various embodiments. The first semiconductor structure 10A in FIG. 3 is similar to the first semiconductor structure 10 in FIG. 2I. The differences between the two are explained below.

In the first semiconductor structure 10 of FIG. 2I, the etching process for forming the through hole TH in the first semiconductor substrate 100 stops on the insulation structure 114 of the gate insulation layer 110 (as shown in FIG. 2B), so that the subsequently formed the blanket dielectric layer 160 contacts the bottom surface 114b of the insulation structure 114 (as shown in FIG. 2C). However, in the first semiconductor structure 10A of FIG. 3, the etching process for forming the through hole TH stops on the conductive pad 124 of the gate electrode layer 120, so that the aforementioned etching process forms an opening in the insulation structure 114, and the subsequently formed blanket dielectric layer 160 contacts the sidewall of the aforementioned opening (which may be referred to as the sidewall of the insulation structure 114). Therefore, in the process of the first semiconductor structure 10A, the step of etching the blanket dielectric layer 160 (similar to the step of FIG. 2D) may expose the conductive pad 124 without etching the insulation structure 114.

In addition, in the first semiconductor structure 10A of FIG. 3, the CMP process for grinding the metal material in the through hole TH (similar to the step of FIG. 2F) stops on the buffer layer 150, and the materials beyond the buffer layer 150 (including the metal layer 184 and the barrier layer 182, the blanket dielectric layer 160 and the mask layer 170 above the buffer layer 150 shown in FIG. 2E) are removed in the CMP process. In the first semiconductor structure 10A of FIG. 3, a portion of the blanket dielectric layer beyond the buffer layer 150 is removed during the CMP process, remaining the dielectric layer 160′. In some embodiments, a portion of the mask layer beyond the buffer layer 150 is removed during the CMP process, remaining the mask layer 170′. In some embodiments, the mask layer 170′ is laterally disposed between the barrier layer 182′ and the dielectric layer 160′. A portion of the barrier layer 182′ is in contact with the dielectric layer 160′, and another portion of the barrier layer 182′ is in contact with the mask layer 170′.

In some implementations, the first semiconductor structure 10A and the second semiconductor structure 20 are bonded together using a method similar to that disclosed in FIG. 2J to obtain an image sensor device.

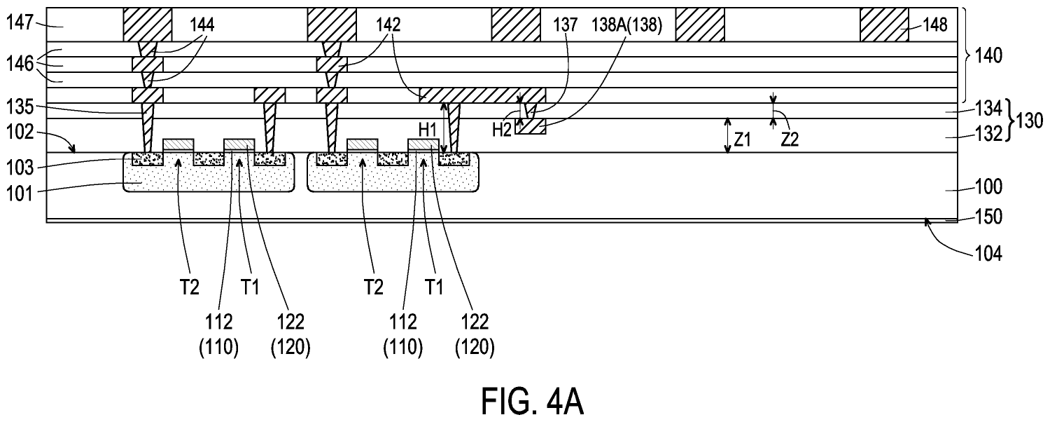

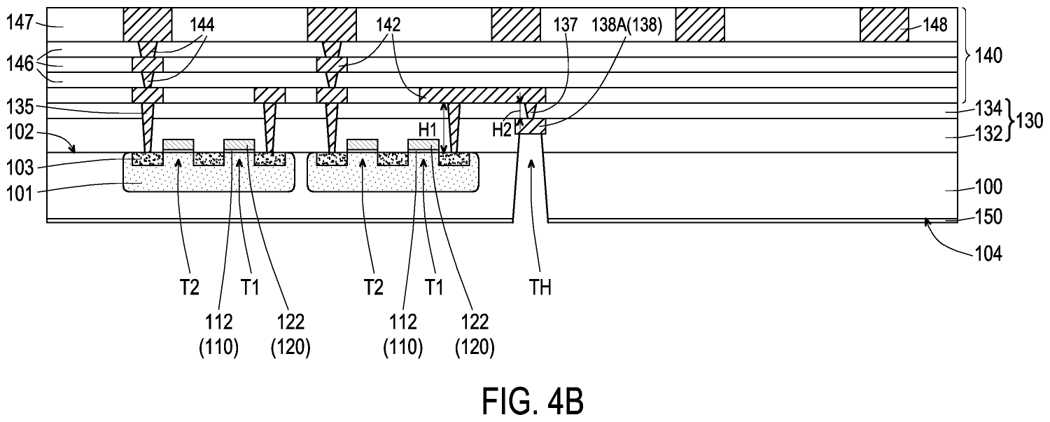

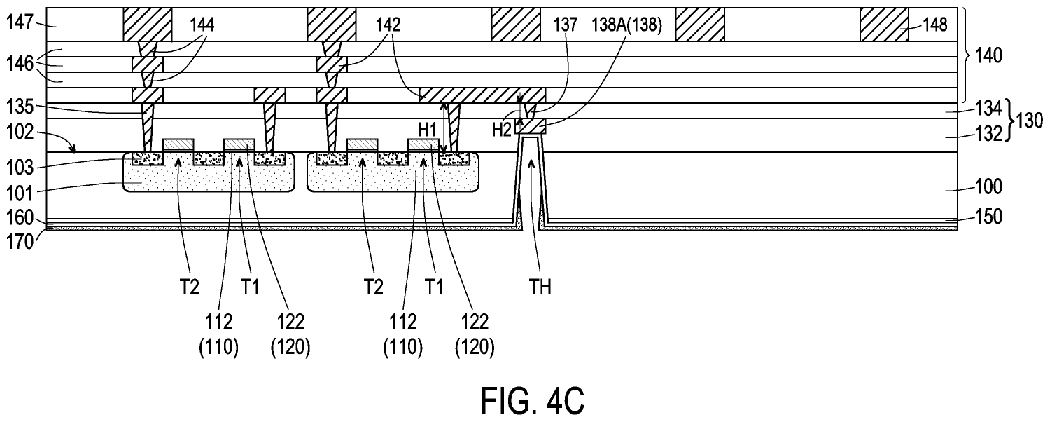

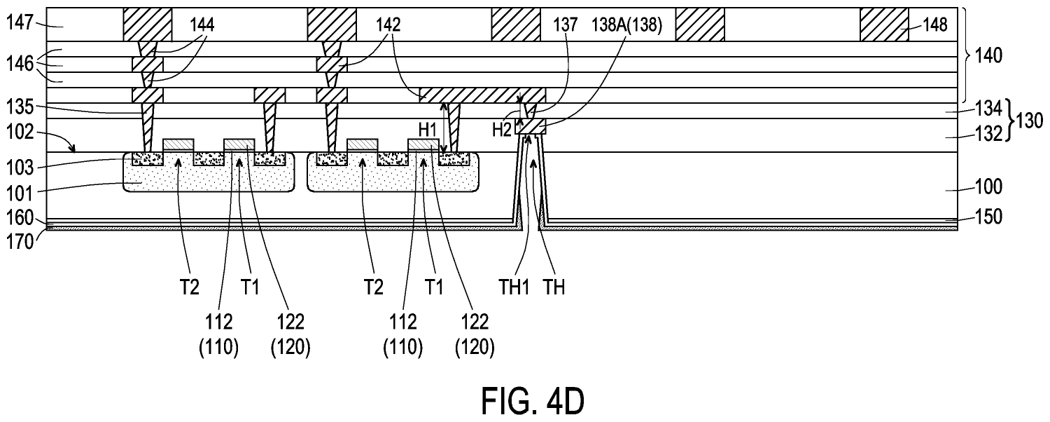

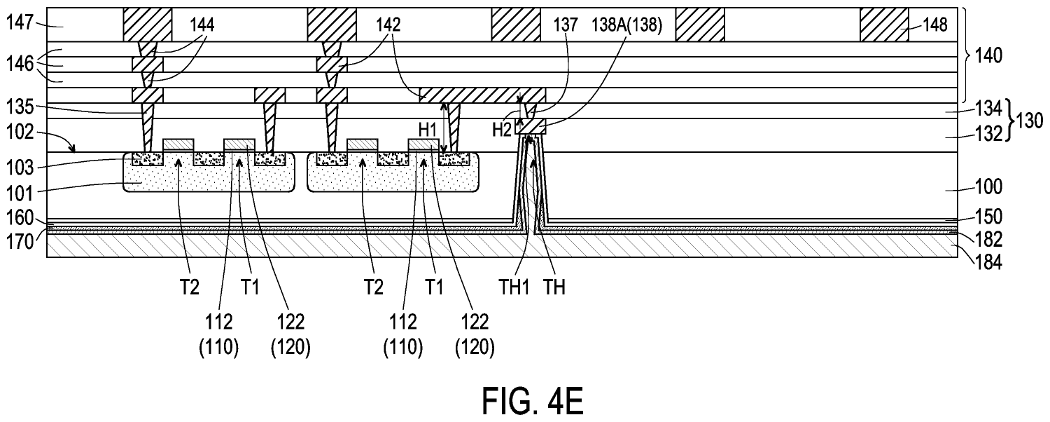

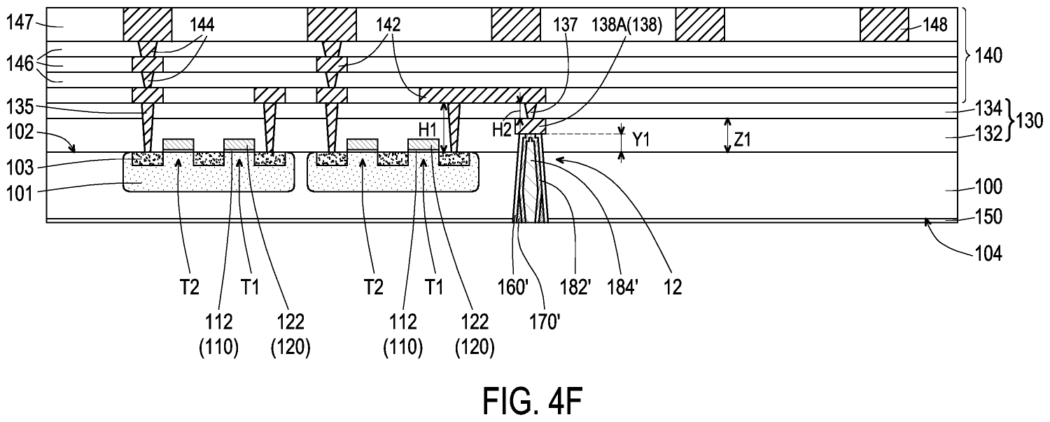

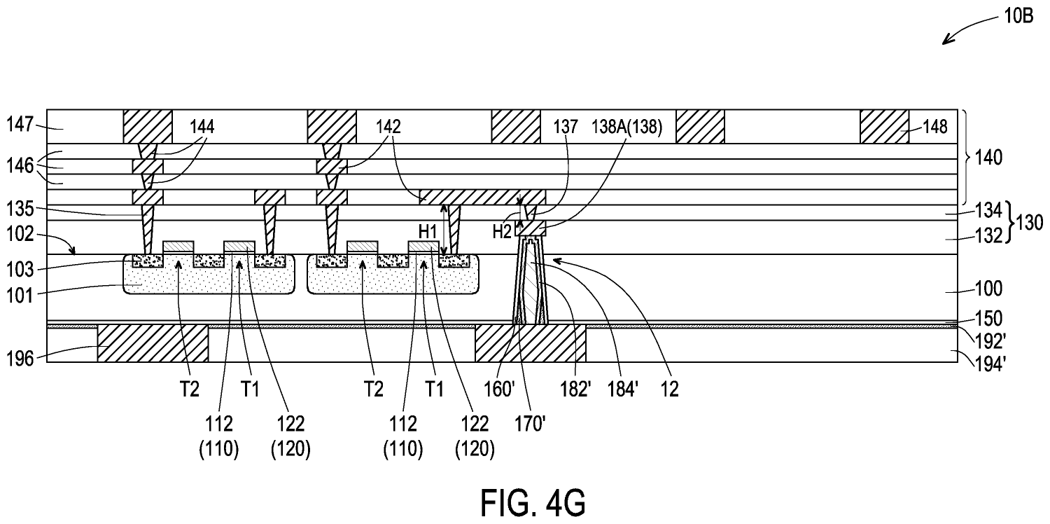

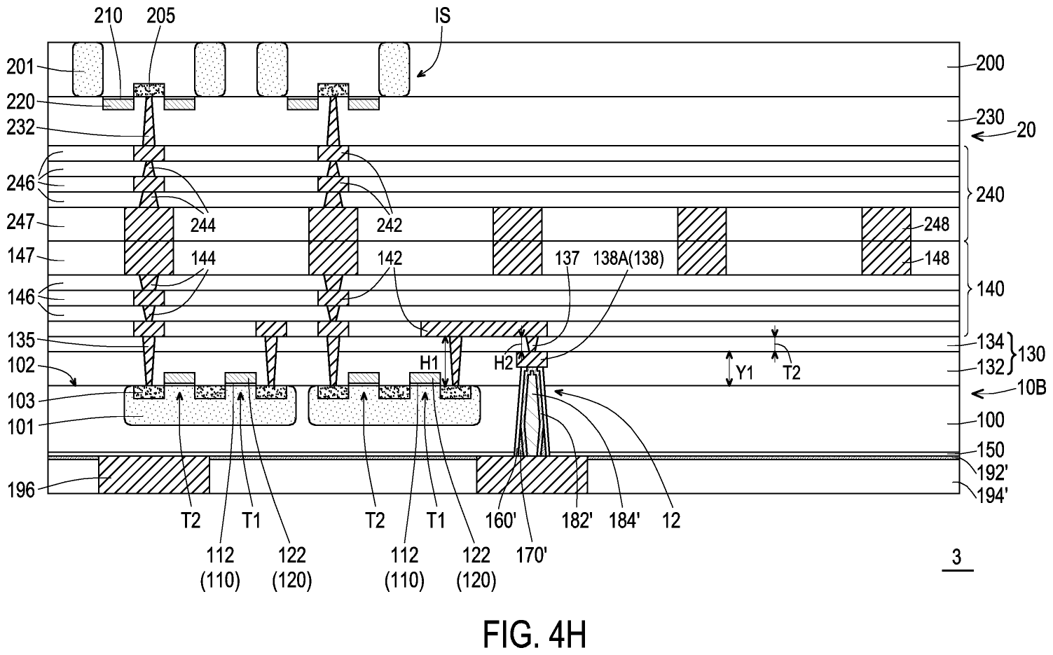

FIGS. 4A to 4H are schematic cross-sectional views of a fabrication method of an embodiment image sensor device 3 in accordance with various embodiments. The structure in FIG. 4A is similar to the structure in FIG. 2A, with the following differences: In the structure of FIG. 4A, the gate insulation layer 110 does not include the insulation structure 114 (as shown in FIG. 2A), the gate electrode layer 120 does not include conductive pad 124 (as shown in FIG. 2A), and the interlayer conductive layer 138 includes a conductive pad 138A.

Referring to FIG. 4A, the conductive pad 138A is embedded in the ILD structure 130 and located between the first ILD layer 132 and the second ILD layer 134. A portion of the ILD structure 130 (such as a portion of the first ILD layer 132) is located between the conductive pad 138A and the first semiconductor substrate 100. The conductive via 137 is embedded in the ILD structure 130 and disposed over the conductive pad 138A. In some embodiments, the source/drain contact vias 135 is penetrating through the first ILD layer 132 and the second ILD layer 134. In some embodiments, the conductive via 137 is penetrating through the second ILD layer 134, but not penetrating through the first ILD layer 132. A height H1 of the source/drain contact via 135 is greater than a height H2 of the conductive via 137.

Referring to FIG. 4B, a through hole TH is formed in the first semiconductor substrate 100 by a wet etching process, a dry etching process, or a combination thereof. In some embodiments, the through hole TH passes through both the buffer layer 150, the first semiconductor substrate 100, and the first ILD layer 132, stopping at the conductive pad 138A. In this embodiment, the first ILD layer 132 is located between the first semiconductor substrate 100 and the conductive pad 138A, which helps to reduce the contamination of the first semiconductor substrate 100 by ions from the conductive pad 138A during the formation of the through hole TH.

Referring to FIG. 4C, a blanket dielectric layer 160 is formed over the back side 104 of the first semiconductor substrate 100. The blanket dielectric layer 160 is formed on the buffer layer 150 and in the through hole TH. The blanket dielectric layer 160 covers the sidewalls of the through hole TH and the conductive pad 138A exposed by the through hole TH. The blanket dielectric layer 160 is in contact with the conductive pad 138A.

A mask layer 170 is disposed above the blanket dielectric layer 160. The mask layer 170 is formed over the back side 104 of the first semiconductor substrate 100. In some embodiments, part of the mask layer 170 is filled in the through hole TH, but does not completely cover the blanket dielectric layer 160 within the through hole TH. In other words, the part of the mask layer 170 is filled into the through hole TH and has an opening that exposes the blanket dielectric layer 160 in the through hole TH. The width of the opening in mask layer 170 is smaller than that of the through hole TH.

Referring to FIG. 4D, an etching process is performed on the blanket dielectric layer 160 to form a through hole TH1 passing through the blanket dielectric layer 160. In some embodiments, the width of the through hole TH is greater than that of the through hole TH1.

In some embodiments, the mask layer 170 is used as a mask to perform an etching process. This process etches the blanket dielectric layer 160 located at the bottom of the through hole TH, thereby exposing the conductive pad 138A.

Referring to FIG. 4E, a barrier material layer 182 is formed over the mask layer 170 and fills into the through holes TH, TH1. In some embodiments, the barrier material layer 182 comes into contact with the blanket dielectric layer 160, the sidewalls of the through holes TH1, and the conductive pad 138A.

A metal layer 184 is then deposited over the barrier material layer 182 and into the through hole TH (or the through holes TH, TH1). In some embodiments, the metal layer 184 may consist of copper or copper alloys, and the barrier material layer 182 may include a nitride (such as titanium nitride, tantalum nitride, or the like) to prevent, for example, the diffusion of copper ions. In other embodiments, the metal layer 184 may comprise other metal materials (such as tungsten), and the barrier material layer 182 can be omitted. In some embodiments, the metal layer 184 and the conductive pad 138A includes the same materials.

Referring to FIG. 4F, a CMP process is performed to remove excess materials from the metal layer 184 and the barrier layer 182, thereby forming the conductive plug 184′ and the barrier layer 182′. The conductive plug 184′ is embedded within the first semiconductor substrate 100. In this embodiment, the CMP process stops at the buffer layer 150, and any materials extending beyond the buffer layer 150 are removed during the CMP process. In some embodiments, a portion of the blanket dielectric layer 160 beyond the buffer layer 150 are removed during the CMP process, remaining the dielectric layer 160′. In some embodiments, a portion of the mask layer 170 beyond the buffer layer 150 are removed during the CMP process, remaining the mask layer 170′.

In this embodiment, a TSV 12 includes the dielectric layer 160′, the barrier layer 182′, and the conductive plug 184′. The TSV 12 is extending from the back side 104 of the first semiconductor substrate 100 to beyond the front side 102 of the first semiconductor substrate 100. In this instance, the TSV 12 penetrates through the first ILD layer 132 and is in contact with the conductive pad 138A. In some embodiments, a depth Y1 of the TSV 12 beyond the front side 102 of the first semiconductor substrate 100 is less than or equal to a thickness Z1 of the first ILD layer 132.

The TSV 12 is electrically connected with the conductive via 137 through the conductive pad 138A, and further electrically connected with the transistor T1 through the interconnect structure 140 and the source/drain contact via 135.

In this embodiment, since the TSV 12 does not extend through the ILD structure 130, the resulting TSV 12 may have a smaller depth, for example, ranging from 0.1 micrometers to 3 micrometers. Due to the reduction in the depth of the TSV 12, the TSV 12 may have a smaller critical dimension (CD), for instance, ranging from 0.05 micrometers to 3 micrometers.

Then, a backside circuit is formed on the back side 104 of the first semiconductor substrate 100, as shown in FIG. 4G. The process for forming a backside circuit can be referred to in FIGS. 2G to 2I and their related descriptions.

Finally, the first semiconductor substrate 10B shown in FIG. 4G is bonded with the second semiconductor 20 as shown in FIG. 4H. The bonding process can be referred to in FIG. 2J and the related descriptions.

The image sensors IS are electrically connected to the transistors T1, T2 via the interconnect structures 140, 240. In some embodiments, reducing the distance between the TSV 12 and the transistor T1 may reduce the signal transmission path between the image sensor IS and the corresponding TSV 12, thereby improving the RC delay problem. In some embodiments, the TSV 12 is overlapping with the pixel area composed of an array of the image sensors IS. For example, the TSV 12 is overlapping with the second semiconductor substrate 200 between two adjacent image sensors IS or overlapping with the image sensor IS.

In some embodiments, the image sensor device 3 includes the second semiconductor structure 20 and the first semiconductor structure 10B, but this disclosure is not limited thereto. In other embodiments, the image sensor device 3 further includes other semiconductor structures, such as ASIC, bonded to the back side of the first semiconductor structure 10B. In some embodiments, optical elements such as color filters, lens, or other optical elements may be placed on the back side of the second semiconductor structure 20 facing away from the first semiconductor structure 10B, but this disclosure is not limited thereto.

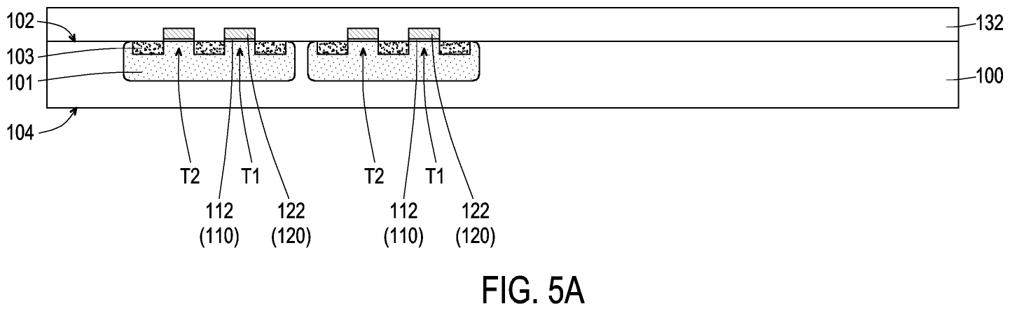

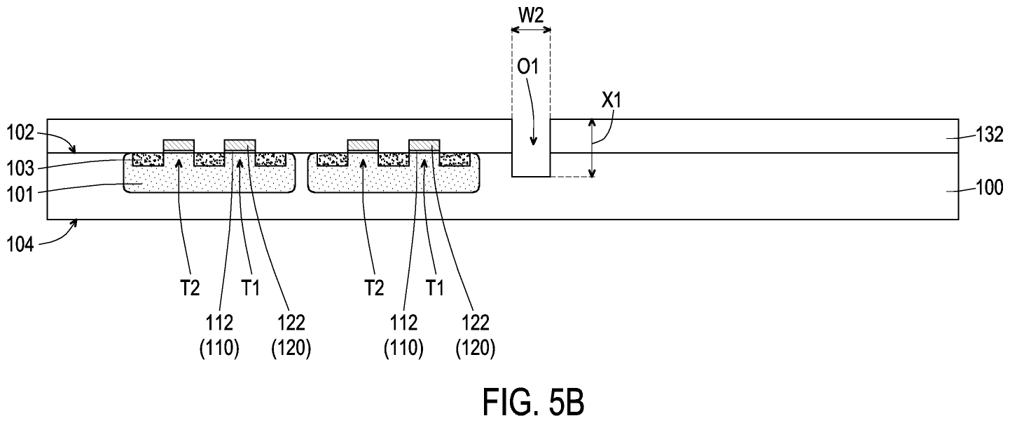

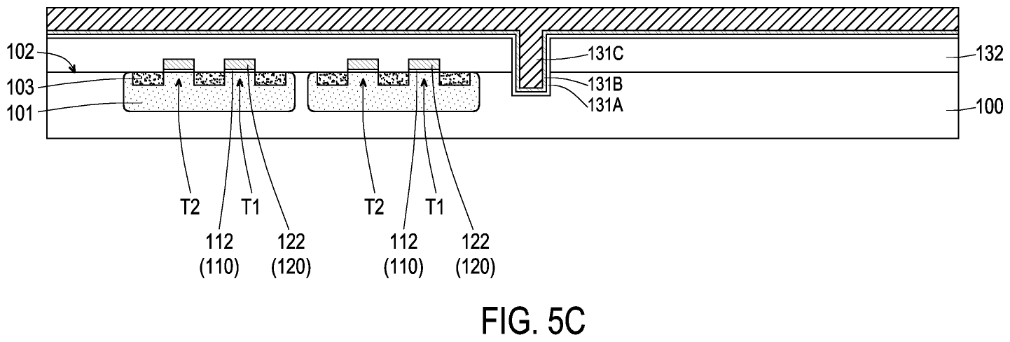

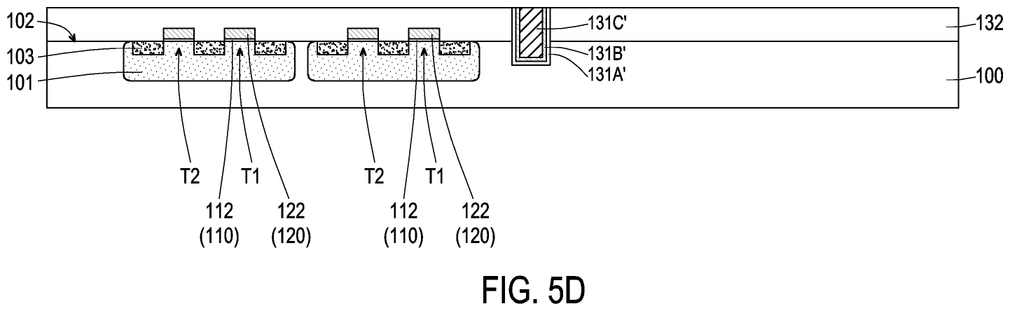

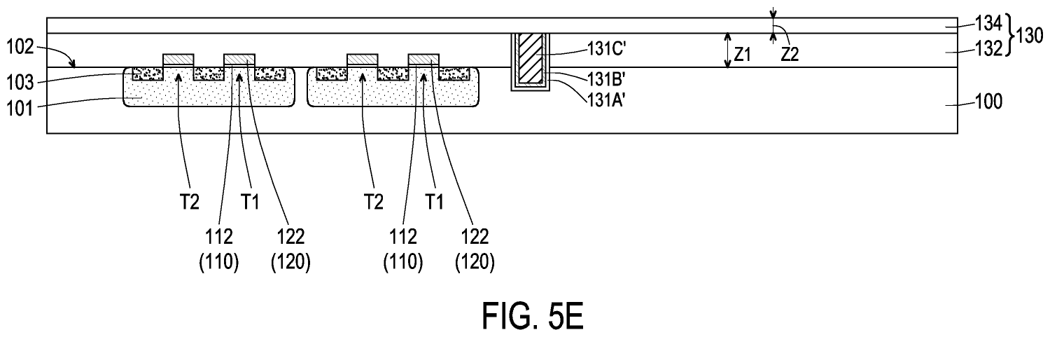

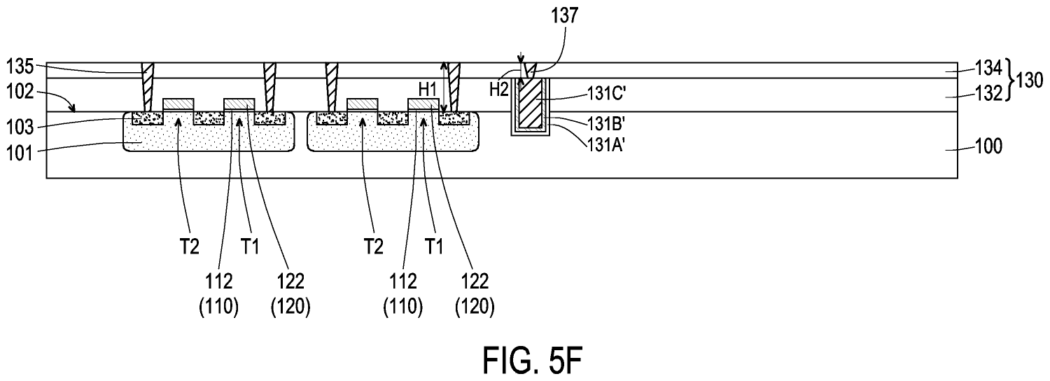

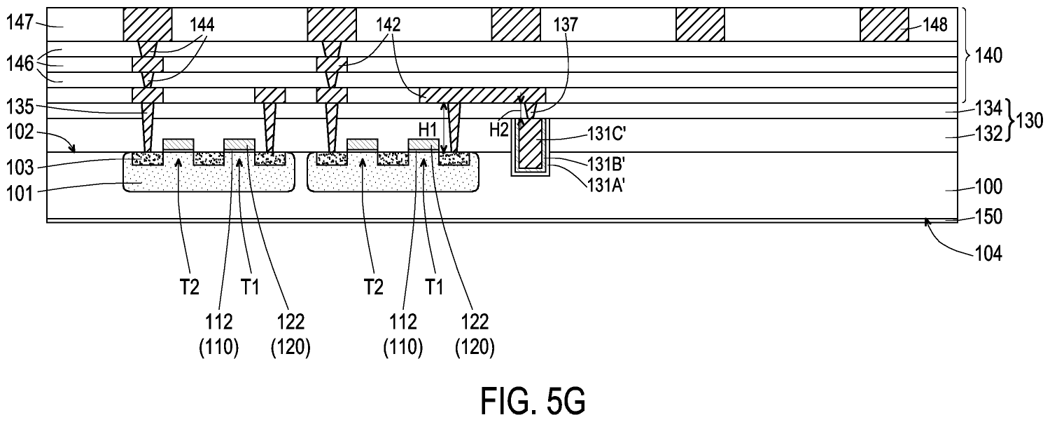

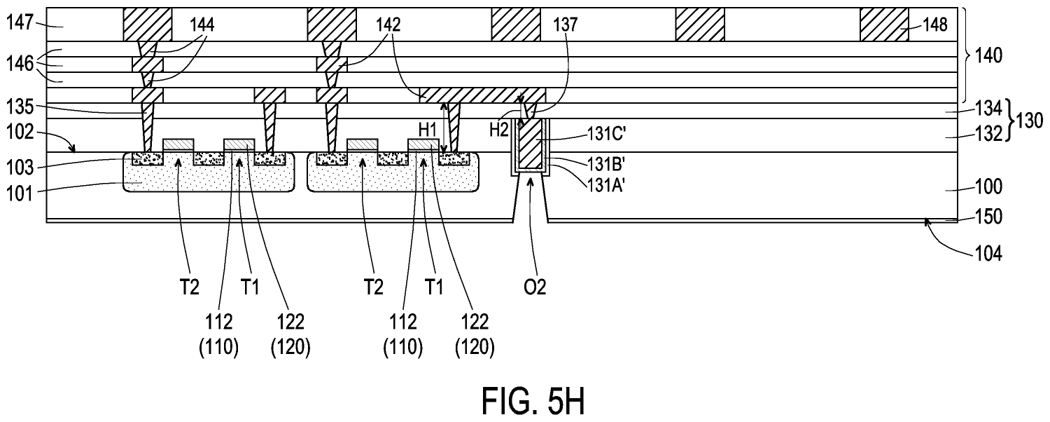

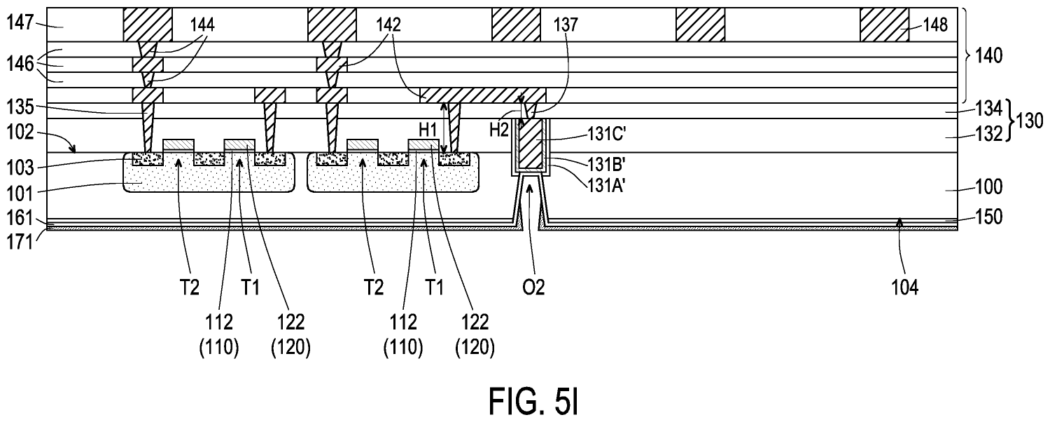

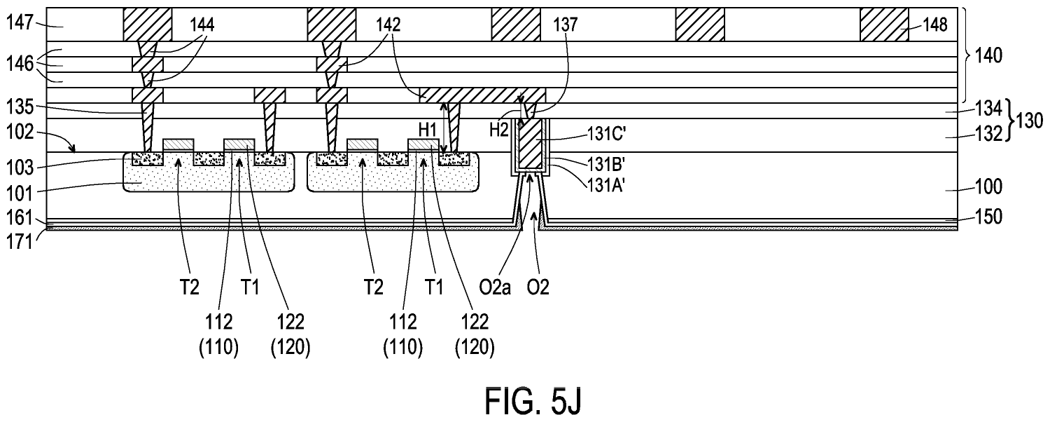

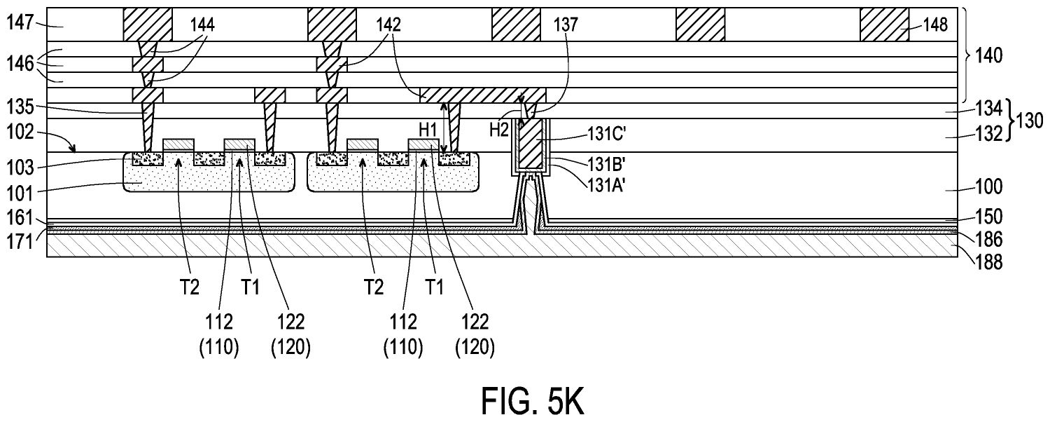

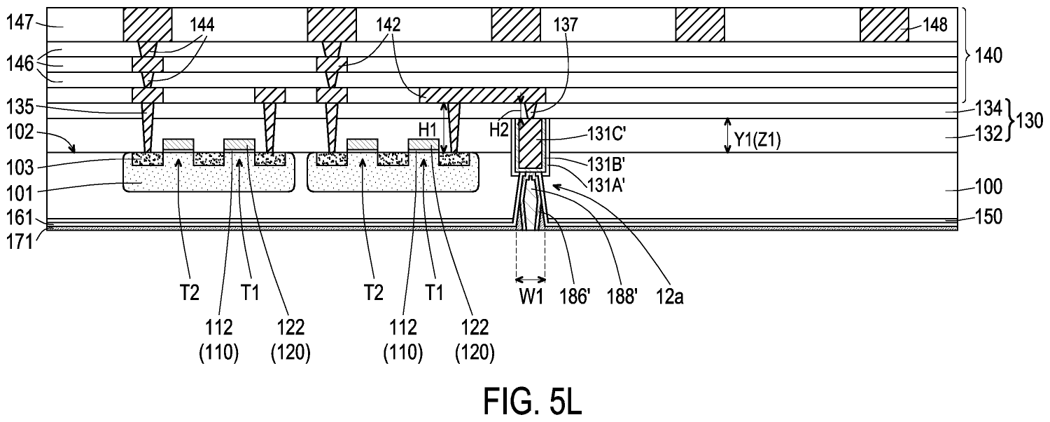

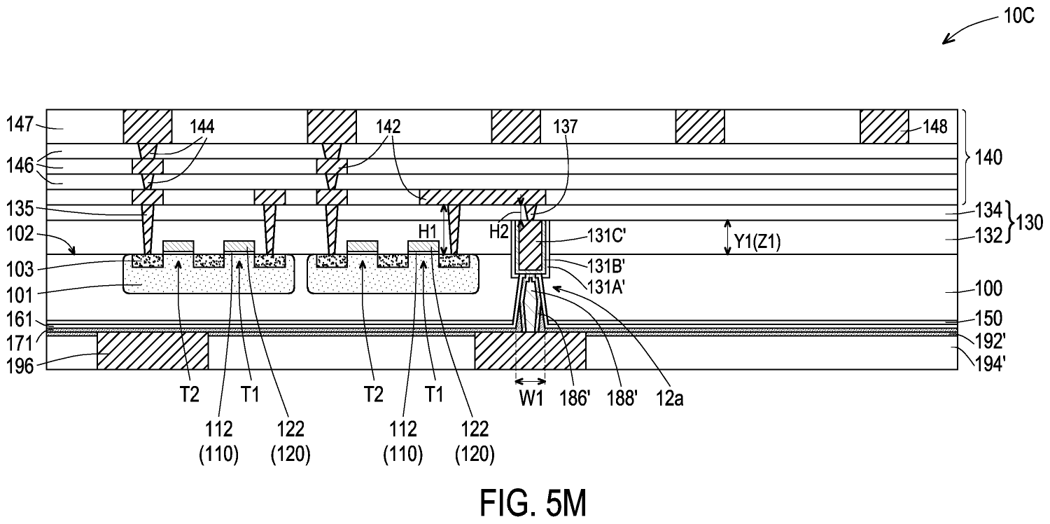

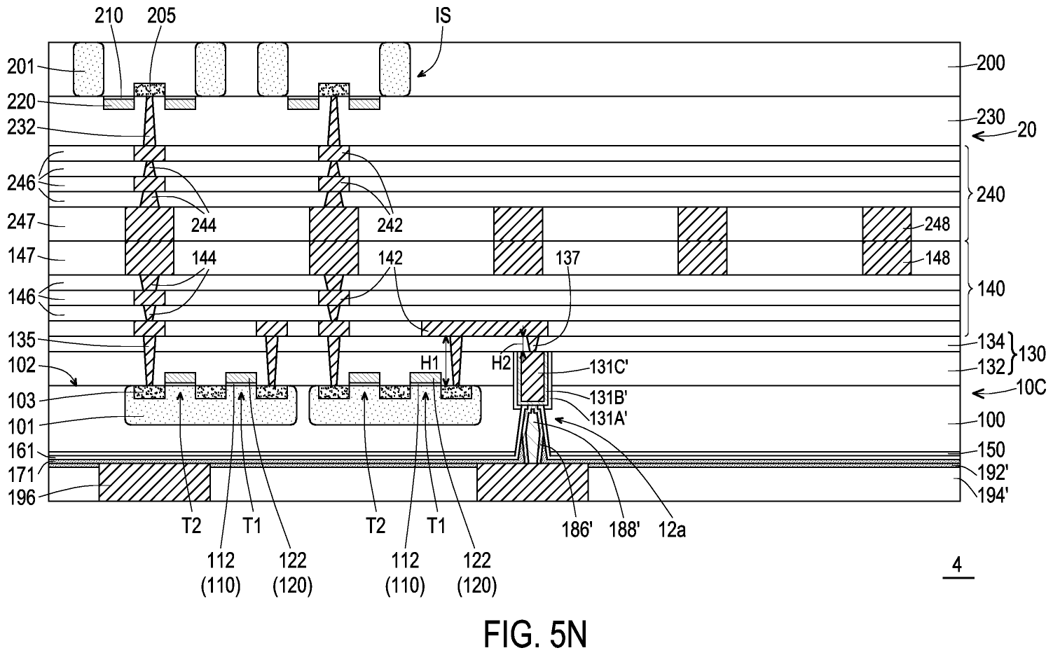

FIGS. 5A to 5N are schematic cross-sectional views of a fabrication method of an embodiment image sensor device 4 in accordance with various embodiments. Referring to FIG. 5A, a first semiconductor substrate 100 is provided. The read-out circuits are formed on the front side 102 of the first semiconductor substrate 100. In some embodiments, the read-out circuits are arranged in rows and columns, and each read-out circuit includes logic devices, such as a transistor T1 and a transistor T2. In some embodiments, the transistor T1 is a row selector transistor, and the transistor T2 is a source follower transistor. In some embodiments, each read-out circuit further includes a reset transistor (not shown) electrically connected with the transistor T2.

The channel features 101 and the source/drain features 103 of the transistors T1 and the transistors T2 may be formed by performing a plurality of ion implantation processes on the first semiconductor substrate 100. The ion implantation processes may include multiple implant steps and may use different types of dopants, implant dosages, and implantation energies. The ion implantation processes may also use different masks that have different patterns and opening sizes.

A gate insulation layer 110 and the gate electrode layer 120 are formed over the front side 102 of the first semiconductor substrate 100. The gate insulation layer 110 includes gate insulators 112. In some embodiments, the gate insulators 112 are separated from each other, but the disclosure is not limited thereto. In other embodiments, the gate insulators 112 are connected with each other. In some embodiments, the thickness of the gate insulation layer 110 is in a range between approximately 10 Angstroms to approximately 1000 Angstroms.

The gate electrode layer 120 includes gate electrodes 122. The gate insulators 112 are located between the gate electrodes 122 and the first semiconductor substrate 100. In some embodiments, the sidewalls of the gate electrodes 122 are aligned with the sidewalls of the gate insulators 112, but the disclosure is not limited thereto. In some embodiments, the thickness of the gate electrode layer 120 is in a range between approximately 500 Angstroms to approximately 3000 Angstroms.

A first ILD layer 132 is disposed over the front side 102 of the first semiconductor substrate 100 and covers the transistors T1 and the transistors T2.

Referring to FIG. 5B, one or more etching processes are performed to form an opening O1 in the first ILD layer 132 and the first semiconductor substrate 100. In some embodiments, a patterned photoresist layer (not shown) is formed over the first ILD layer 132. Wet etching process and/or dry etching process is then performed using the patterned photoresist layer as a mask to form the opening O1. In some embodiments, the opening O1 extends through the first ILD layer 132 and into the first semiconductor substrate 100 from the front side 102 of the first semiconductor substrate 100, but not extending to the back side 104 of the first semiconductor substrate 100.

In some embodiments, if the depth of the opening O1 is deeper, the width of the opening O1 may be wider under a fixed aspect ratio. In some embodiments, since the opening O1 does not need to penetrate the first semiconductor substrate 100, the width of the opening O1 may be reduced by making the depth of the opening O1 shallower. In some embodiments, the depth X1 of the opening O1 is ranging from 0.01 micrometers to 5 micrometers, and a width W2 of the opening O1 is ranging from 0.01 micrometers to 5 micrometers.

Referring to FIG. 5C, a first blanket dielectric layer 131A is formed over the first ILD layer 132 and filled into the opening O1. The first blanket dielectric layer 131A covers the sidewalls and the bottom surface of the opening O1. In some embodiments, the first blanket dielectric layer 131A includes oxides (such as silicon oxide) or other dielectric materials. In some embodiments, the methods for forming the first blanket dielectric layer 131A include PVD, CVD, ALD, or the like.

A first barrier material layer 131B is formed over the first blanket dielectric layer 131A and fills into the opening O1. In some embodiments, the first barrier material layer 131B is in contact with the first blanket dielectric layer 131A.

A first metal layer 131C is then deposited over the first barrier material layer 131B and into the opening 01. In some embodiments, the first metal layer 131C may consist of copper or copper alloys, and the first barrier material layer 131B may include a nitride (such as titanium nitride, tantalum nitride, or the like) to prevent, for example, the diffusion of copper ions. In other embodiments, the first metal layer 131C may comprise other metal materials (such as tungsten), and the first barrier material layer 131B can be omitted.

Referring to FIG. 5D, a CMP process is performed to remove excess materials from the first metal layer 131C, the first barrier material layer 131B, and the first blanket dielectric layer 131A, thereby forming the first conductive plug 131C′, the first barrier layer 131B′, and the first dielectric layer 131A′. The first dielectric layer 131A′ is laterally disposed between the first conductive plug 131C′ and the first semiconductor substrate 100. The first barrier layer 131B′ is laterally disposed between the first conductive plug 131C′ and the first dielectric layer 131A′.

In this embodiment, the CMP process stops at the first ILD layer 132. The portions of the first metal layer 131C, the first barrier material layer 131B, and the first blanket dielectric layer 131A that extend beyond the first ILD layer 132 are removed during the CMP process. In other embodiments, the CMP process stops at the first blanket dielectric layer 131A.

The first conductive plug 131C′, the first barrier layer 131B′, and the first dielectric layer 131A′ extend from the top surface of the first ILD layer 132 to the front side 102 of the first semiconductor substrate 100, and into the first semiconductor substrate 100 from the front side 102.

Referring to FIG. 5E, the second ILD layer 134 is formed over the first ILD layer 132 and covers the first conductive plug 131C′, the first barrier layer 131B′, and the first dielectric layer 131A′. That is, the first conductive plug 131C′, the first barrier layer 131B′, and the first dielectric layer 131A′ are embedded in the ILD structure 130. The first conductive plug 131C′ is extending from the ILD structure 130 into the first semiconductor substrate 100.

In some embodiments, the first ILD layer 132 has a thickness Z1 in a range between approximately 10 Angstroms to approximately 3000 Angstroms. In some embodiments, the second ILD layer 134 has a thickness Z2 in a range between approximately 10 Angstroms to approximately 3000 Angstroms.

Referring to FIG. 5F, source/drain contact vias 135 and the conductive via 137 are formed within the ILD structure 130. In some embodiments, after forming the second ILD layer 134, one or more etching processes are performed to create multiple openings in the ILD structure 130. Some of these openings expose parts of the source/drain features 103, while others expose the first conductive plug 131C′. A metal material (e.g., copper, aluminum, tungsten, and so on) is then filled into these openings. Subsequently, a planarization process is performed to remove excess metal material, thereby forming the source/drain contact vias 135 and the conductive via 137 within the ILD structure 130.

In some embodiments, in addition to forming the source/drain contact vias 135 and the conductive via 137 within the ILD structure 130, gate contact vias (not shown) are also formed over the gate electrodes 122 within the ILD structure 130.

The source/drain contact vias 135 are extending from a top surface of the ILD structure 130 to corresponding source/drain features 103 of the transistors T1, T2, and electrically connected with the corresponding source/drain features 103 of the transistors T1, T2. In some embodiments, the source/drain feature 103, located between one transistor T1 and an adjacent transistor T2, is not connected with the source/drain contact vias 135, but the disclosure is not limited thereto. In some embodiments, the source/drain contact vias 135 is penetrating through the first ILD layer 132 and the second ILD layer 134.

The conductive via 137 are extending from the top surface of the ILD structure 130 into the ILD structure 130. The conductive via 137 is disposed over and electrically connected with the first conductive plug 131C′. The conductive via 137 is landed on the first conductive plug 131C′. In some embodiments, the conductive via 137 is penetrating through the second ILD layer 134, but not penetrating through the first ILD layer 132. In some embodiments, a height H1 of the source/drain contact via 135 is greater than a height H2 of the conductive via 137.

Referring to FIG. 5G, an interconnect structure 140 is disposed over the ILD structure 130 and electrically connected with the conductive via 137 and the source/drain contact vias 135. In certain embodiments, multiple transistors T1 are arranged in the same column and are divided into several groups. Each group contains one or more transistors T1, and the transistors T1 within each group are electrically interconnected through the interconnect structure 140. In some embodiments, the transistors T1 in the same group are electrically connected to the same conductive via 137 through the interconnect structure 140. For example, one of the source/drain features 103 of a transistor T1 is electrically connected to the corresponding source/drain feature 103 of an adjacent transistor T1 through the interconnect structure 140. Furthermore, in this embodiment, the source/drain features 103 of the transistors T1 are electrically connected to the conductive via 137, but this disclosure is not limited to this. In other embodiments, the gate electrodes 122 of the transistors T1 or the transistors T2 are electrically connected to the conductive vias 137.

The interconnect structure 140 may include a plurality of metallization layers 142 and a plurality of metal vias 144. The number of metallization layers 142 may vary according to design specifications of the semiconductor device. The metallization layers 142 closest to the ILD structure 130 can be referred to as the M1 layer. The M1 layer is in contact with the source/drain contact vias 135 and the conductive via 137. The metallization layers 142 at different levels are electrically interconnected through the metal vias 144. The metallization layers 142 and the metal vias 144 are located within the inter-metallization dielectric (IMD) layers 146.

The topmost layer of the interconnect structure 140 includes bonding pads 148 and a bonding layer 147. Both the bonding pads 148 and the bonding layer 147 are used in the hybrid bonding process. Specifically, the bonding pads 148 are used for metal-to-metal bonding, while the bonding layer 147 is used for insulator-to-insulator (or dielectric-to-dielectric) bonding during the bonding process.

A buffer layer 150 is formed on the back side 104 of the first semiconductor substrate 100. In some embodiments, the buffer layer 150 comprises oxide (such as silicon oxide) or other dielectric materials. In certain embodiments, the buffer layer 150 is utilized to protect the back side 104 of the first semiconductor substrate 100 during subsequent chemical mechanical planarization (CMP) or etching processes.

Referring to FIG. 5H, an opening O2 is formed in the first semiconductor substrate 100 by a wet etching process, a dry etching process, or a combination thereof. In some embodiments, the opening O2 passes through the buffer layer 150 and extending into the first semiconductor substrate 100 from the back side 102, and stopping at the first barrier layer 131B′ and/or the first conductive plug 131C′.

In some embodiments, a recess is formed on the back side 102 of the first semiconductor substrate 100 using dry etching. The recess is overlapping with the first conductive plug 131C′, but does not extend through the first barrier layer 131B′ and the first dielectric layer 131A′, to prevent damage to the first conductive plug 131C′ caused by the dry etching process and contamination of the first semiconductor substrate 100. Subsequently, the first dielectric layer 131A′ at the bottom of the aforementioned recess is removed using wet etching, exposing the first barrier layer 131B′ and/or the first conductive plug 131C′.

Referring to FIG. 51, a blanket dielectric layer 161 (which is referred to as the second dielectric layer in some embodiments) is formed over the back side 104 of the first semiconductor substrate 100. The blanket dielectric layer 161 is formed on the buffer layer 150 and in the opening O2. The blanket dielectric layer 161 covers the sidewalls of the opening O2 and is in contact with the first dielectric layer 131A′. The blanket dielectric layer 161 also covers the first barrier layer 131B′ and/or the first conductive plug 131C′ that is exposed by the opening O2.

In some embodiments, the blanket dielectric layer 161 includes oxides (such as silicon oxide) or other dielectric materials. In some embodiments, the methods for forming the blanket dielectric layer 161 include PVD, CVD, ALD, or the like.

A mask layer 171 is disposed above the blanket dielectric layer 161. The mask layer 171 is formed over the back side 104 of the first semiconductor substrate 100. In some embodiments, by adjusting the deposition rate of the mask layer 171, it is ensured that the mask layer 171 does not fill into the opening O2. Therefore, there is no need to use a photomask process to pattern the mask layer 170. In some embodiments, the material of the mask layer 171 includes nitrides (such as silicon nitride) or other dielectric materials.

In some embodiments, part of the mask layer 171 is filled in the opening O2, but does not completely cover the blanket dielectric layer 161 within the opening O2. In other words, the part of the mask layer 171 is filled into the opening O2 and has an opening that exposes the blanket dielectric layer 161 in the opening O2. The width of the opening in mask layer 171 is smaller than that of the opening O2.

Referring to FIG. 5J, an etching process is performed on the blanket dielectric layer 161 to form a through hole O2a passing through the blanket dielectric layer 161. In some embodiments, the width of the opening O2 is greater than that of the through hole O2a.

In some embodiments, the mask layer 171 is used as a mask to perform an etching process. This process etches the blanket dielectric layer 161 located at the bottom of the opening O2, thereby exposing the first barrier layer 131B′ and/or the first conductive plug 131C′.

In some embodiments, the blanket dielectric layer 161 is passing through the first dielectric layer 131A′ and in contact with the first barrier layer 131B′ and/or the first conductive plug 131C′, but the disclosure is not limited thereto. In other embodiments, the opening O2 does not extend through the first dielectric layer 131A′, and the blanket dielectric layer 161 is separated from the first barrier layer 131B′ by the first dielectric layer 131A′. In this scenario, the etching process is used to remove the blanket dielectric layer 161 and the first dielectric layer 131A′ at the bottom of the opening O2 to form the opening exposing the first barrier layer 131B′ and/or the first conductive plug 131C′.

Referring to FIG. 5K, a barrier material layer 186 and a metal layer 188 are formed above the mask layer 171. In some embodiments, the metal layer 188 may consist of copper or copper alloys, and the barrier material layer 186 may include a nitride (such as titanium nitride, tantalum nitride, or the like) to prevent, for example, the diffusion of copper ions. In other embodiments, the metal layer 188 may comprise other metal materials (such as tungsten), and the barrier material layer 186 can be omitted.

Referring to FIG. 5L, a CMP process is used to remove the excess portions of the barrier material layer 186 and the metal layer 188, thereby forming the second barrier layer 186′ and the second conductive plug 188′. In this embodiment, the CMP process stops at the mask layer 171. However, this disclosure is not limited thereto. In other embodiments, the CMP process stops at the blanket dielectric layer 161 or the buffer layer 150, and any materials extending beyond the blanket dielectric layer 161 or the buffer layer 150 are removed during the CMP process.

The second conductive plug 188′ and the second barrier layer 186′ are formed in the opening O2. The second conductive plug 188′ is extending from the back side 104 of the first semiconductor substrate 100 into the first semiconductor substrate 100, and electrically connected with the first conductive plug 131C′. The second barrier layer 186′ is laterally disposed between the second conductive plug 188′ and the blanket dielectric layer 161. The second barrier layer 186′ is penetrating through the first dielectric layer 131A′ and in contact with the first barrier layer 131B′. The blanket dielectric layer 161 is laterally disposed between the second conductive plug 188′ and the first semiconductor substrate 100 and between the second barrier layer 186′ and the first semiconductor substrate 100.

In this embodiment, a TSV 12a includes the first dielectric layer 131A′, the first barrier layer131B′, the first conductive plug 131C′, the second conductive plug 188′, the second barrier layer 186′, and the blanket dielectric layer 161. In some embodiments, a depth Y1 of the TSV 12a beyond the front side 102 of the first semiconductor substrate 100 is less than or equal to a thickness Z1 of the first ILD layer 132. In some instances, the depth Y1 is approximately equal to the thickness of the first ILD layer 132.

The conductive via 137 is located above and electrically connected with the TSV 12a. In this embodiment, since the TSV 12a does not extend through the ILD structure 130, the resulting TSV 12a may have a smaller depth.

Then, a backside circuit is formed on the back side 104 of the first semiconductor substrate 100, as shown in FIG. 5M. The process for forming a backside circuit can be referred to in FIGS. 2G to 2I and their related descriptions.

Finally, the first semiconductor substrate 10C shown in FIG. 5M is bonded with the second semiconductor 20 as shown in FIG. 5N. The bonding process can be referred to in FIG. 2J and the related descriptions.

The image sensors IS are electrically connected to the transistors T1, T2 via the interconnect structures 140, 240. In some embodiments, reducing the distance between the TSV 12a and the transistor T1 may reduce the signal transmission path between the image sensor IS and the corresponding TSV 12a, thereby improving the RC delay problem. In some embodiments, the TSV 12a is overlapping with the pixel area composed of an array of the image sensors IS. For example, the TSV 12a is overlapping with the second semiconductor substrate 200 between two adjacent image sensors IS or overlapping with the image sensor IS.

In some embodiments, the image sensor device 4 includes the second semiconductor structure 20 and the first semiconductor structure 10C, but this disclosure is not limited thereto. In other embodiments, the image sensor device 4 further includes other semiconductor structures, such as ASIC, bonded to the back side of the first semiconductor structure 10C. In some embodiments, optical elements such as color filters, lens, or other optical elements may be placed on the back side of the second semiconductor structure 20 facing away from the first semiconductor structure 10C, but this disclosure is not limited thereto.

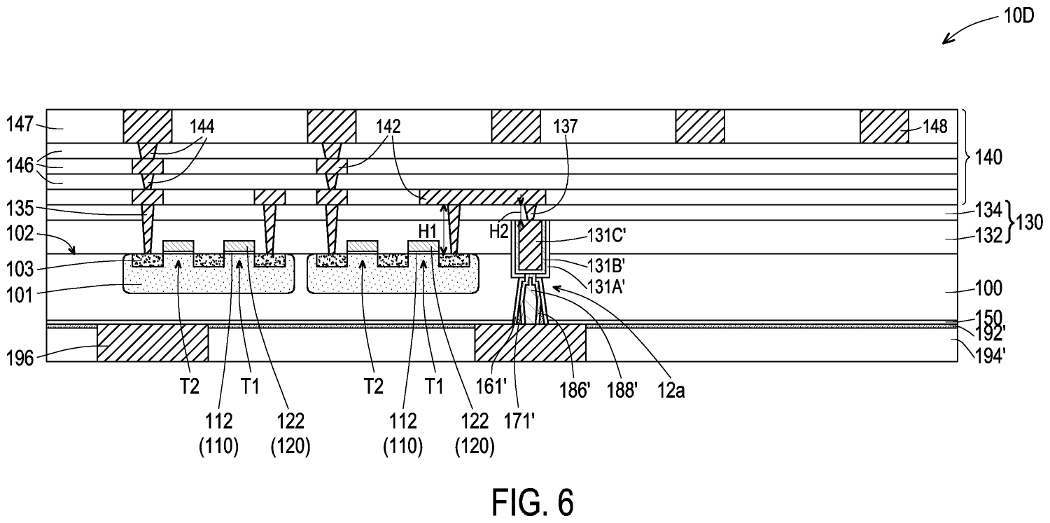

FIG. 6 is a schematic cross-sectional view of an embodiment first semiconductor structure 10D in accordance with various embodiments. The first semiconductor structure 10D in FIG. 6 is similar to the first semiconductor structure 10C in FIG. 5M. The differences between the two are explained below.

In the first semiconductor structure 10C of FIG. 5M, the etching process for forming the opening O2 in the first semiconductor substrate 100 stops on the first barrier layer 131B′, so that the subsequently formed blanket dielectric layer 161 contacts the bottom surface of the first barrier layer 131B′ (as shown in FIG. 5J). However, in the first semiconductor structure 10D of FIG. 6, the etching process for forming the opening O2 stops on the first dielectric layer 131A′, so that the blanket dielectric layer (referred to as the second dielectric layer 161′ after the CMP process) is separated from the first barrier layer 131B′ by the first dielectric layer 131A′. Therefore, in the process of the first semiconductor structure 10D, after the blanket dielectric layer is formed, it is necessary to etch both the blanket dielectric layer 161 and the first dielectric layer 131A′ to expose the first barrier layer 131B′.

In addition, in the first semiconductor structure 10D of FIG. 6, the CMP process for grinding the metal material in the opening O2 (similar to the step of FIG. 5L) stops on the buffer layer 150, and the materials beyond the buffer layer 150 are removed in the CMP process. In the first semiconductor structure 10D of FIG. 6, a portion of the blanket dielectric layer beyond the buffer layer 150 is removed during the CMP process, remaining the second dielectric layer 161′. In some embodiments, a portion of the mask layer beyond the buffer layer 150 is removed during the CMP process, remaining the mask layer 171′. In some embodiments, the mask layer 171′ is laterally disposed between the second barrier layer 186′ and the second dielectric layer 161′.

In some embodiments, the first semiconductor structure 10D and the second semiconductor structure 20 are bonded together using a method similar to that disclosed in FIG. 2J to obtain an image sensor device.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

In accordance with an embodiment, an image sensor device includes a first semiconductor structure and a second semiconductor structure bonding with the first semiconductor structure. The first semiconductor structure includes a first semiconductor substrate and logic devices. The logic devices are disposed on the first semiconductor substrate. A through-substrate via is penetrating through the first semiconductor substrate and located between two of the logic devices. A second semiconductor structure includes a second semiconductor substrate and image sensors. The image sensors are disposed in a pixel area of the second semiconductor substrate. At least one of the image sensors is electrically to at least one of the two of the logic devices.

In accordance with another embodiment, a semiconductor structure includes a semiconductor substrate a transistor, an interlayer dielectric structure, a source/drain contact via, a conductive via, and a through-substrate via. The transistor is disposed on the semiconductor substrate. The interlayer dielectric structure is disposed over the transistor. A source/drain contact via is embedded in the interlayer dielectric structure and extending from a top surface of the interlayer dielectric structure to a source/drain feature of the transistor. A conductive via is embedded in the interlayer dielectric structure and extending from the top surface of the interlayer dielectric structure into the interlayer dielectric structure. A height of the source/drain contact via is greater than a height of the conductive via. The through-substrate via is penetrating through the semiconductor substrate and electrically connected with the conductive via.

In accordance with still another embodiment, an image sensor device includes a first semiconductor substrate, a transistor, a first interlayer dielectric layer, a second interlayer dielectric layer, a source/drain contact via, and a through-substrate via. The first semiconductor substrate includes a front side and a back side opposite to the front side. The transistor is disposed on the front side of the first semiconductor substrate. The first interlayer dielectric layer is disposed over the front side of the first semiconductor substrate. The second interlayer dielectric layer is disposed over the first interlayer dielectric layer. The source/drain contact via is extending through the first interlayer dielectric layer and the second interlayer dielectric layer. The source/drain contact via is electrically connected with the transistor. The through-substrate via is extending from the back side of the first semiconductor substrate to beyond the front side of the first semiconductor substrate. A depth of the through-substrate via beyond the front side of the first semiconductor substrate is less than or equal to a thickness of the first interlayer dielectric layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An image sensor device, comprising:
a first semiconductor structure, comprising:
a first semiconductor substrate;
logic devices, disposed on the first semiconductor substrate; and
a through-substrate via, penetrating through the first semiconductor substrate and located between two of the logic devices; and
a second semiconductor structure bonding with the first semiconductor structure, wherein the second semiconductor structure comprising:
a second semiconductor substrate; and
image sensors, disposed in a pixel area of the second semiconductor substrate, wherein at least one of the image sensors is electrically to at least one of the two of the logic devices.

2. The image sensor device of claim 1, wherein the through-substrate via is overlapping with the pixel area.

3. The image sensor device of claim 1, wherein the first semiconductor structure further comprises:
a gate electrode layer, comprises a gate electrode of the at least one of the two of the logic devices and a conductive pad;
a gate insulation layer, located between the gate electrode and the first semiconductor substrate and between the conductive pad and the first semiconductor substrate, wherein the through-substrate via is penetrating through the gate insulation layer and in contact with the conductive pad.

4. The image sensor device of claim 1, wherein the first semiconductor structure further comprises:
an interlayer dielectric structure, disposed over the logic devices;
a source/drain contact via, embedded in the interlayer dielectric structure and electrically connected with a source/drain feature of the at least one of the two of the logic devices;
a conductive pad, embedded in the interlayer dielectric structure, wherein the through-substrate via is extending into the interlayer dielectric structure and in contact with the conductive pad; and
a conductive via, embedded in the interlayer dielectric structure and disposed over the conductive pad, wherein a height of the source/drain contact via is greater than a height of the conductive via.

5. The image sensor device of claim 4, wherein the first semiconductor structure further comprises:
an interconnect structure, disposed over the interlayer dielectric structure and electrically connected with the conductive via and the source/drain contact via.

6. The image sensor device of claim 4, wherein a portion of the interlayer dielectric structure is disposed between the conductive pad and the first semiconductor substrate.

7. The image sensor device of claim 1, wherein the through-substrate via comprises:
a conductive plug, embedded in the first semiconductor substrate;
a barrier layer, surrounding the conductive plug;
a dielectric layer, disposed between the barrier layer and the first semiconductor substrate; and
a mask layer, disposed between the dielectric layer and the barrier layer, wherein a portion of the barrier layer is in contact with the dielectric layer, and another portion of the barrier layer is in contact with the mask layer.

8. The image sensor device of claim 1, wherein the through-substrate via comprises:
a first conductive plug, extending from a front side of the first semiconductor substrate into the first semiconductor substrate, wherein the logic devices are disposed on the front side of the first semiconductor substrate;
a second conductive plug, extending from a back side of the first semiconductor substrate into the first semiconductor substrate, and electrically connected with the first conductive plug;
a first dielectric layer, laterally disposed between the first conductive plug and the first semiconductor substrate; and
a second dielectric layer, laterally disposed between the second conductive plug and the first semiconductor substrate.

9. The image sensor device of claim 8, wherein the through-substrate via comprises:
a first barrier layer, laterally disposed between the first conductive plug and the first dielectric layer, wherein the second dielectric layer is in contact with the first barrier layer; and
a second barrier layer, laterally disposed between the second conductive plug and the second dielectric layer, wherein the second barrier layer is in contact with the first barrier layer.

10. A semiconductor structure, comprising:
a semiconductor substrate;
a transistor, disposed on the semiconductor substrate;
an interlayer dielectric structure, disposed over the transistor;
a source/drain contact via, embedded in the interlayer dielectric structure and extending from a top surface of the interlayer dielectric structure to a source/drain feature of the transistor;
a conductive via, embedded in the interlayer dielectric structure and extending from the top surface of the interlayer dielectric structure into the interlayer dielectric structure, wherein a height of the source/drain contact via is greater than a height of the conductive via; and
a through-substrate via, penetrating through the semiconductor substrate and electrically connected with the conductive via.

11. The semiconductor structure of claim 10, further comprises:
a gate electrode layer comprising a conductive pad and a gate electrode of the transistor, wherein the conductive pad is located between the through-substrate via and the conductive via; and
a gate insulation layer, located between the gate electrode and the semiconductor substrate and between the conductive pad and the semiconductor substrate, wherein the through-substrate via is penetrating through the gate insulation layer.

12. The semiconductor structure of claim 11, wherein a material of the conductive pad comprises polysilicon.

13. The semiconductor structure of claim 10, wherein the interlayer dielectric structure comprises:
a first interlayer dielectric layer, disposed over the transistor; and
a second interlayer dielectric layer, disposed over the first interlayer dielectric layer; and
a conductive pad, located between the first interlayer dielectric layer and the second interlayer dielectric layer and between the through-substrate via and the conductive via.

14. The semiconductor structure of claim 13, wherein the source/drain contact via is penetrating through the first interlayer dielectric layer and the second interlayer dielectric layer, and the conductive via is penetrating through the second interlayer dielectric layer.

15. The semiconductor structure of claim 10, wherein the through-substrate via comprises:
a first conductive plug, extending from the interlayer dielectric structure into the semiconductor substrate, wherein the conductive via is landed on the first conductive plug; and
a second conductive plug, extending from a back side of the semiconductor substrate into the semiconductor substrate, and electrically connected with the first conductive plug;
a first dielectric layer, laterally disposed between the first conductive plug and the semiconductor substrate; and
a second dielectric layer, laterally disposed between the second conductive plug and the semiconductor substrate, wherein the second dielectric layer is penetrating through the first dielectric layer.

16. An image sensor device, comprising:
a first semiconductor substrate comprising a front side and a back side opposite to the front side;
a transistor, disposed on the front side of the first semiconductor substrate;
a first interlayer dielectric layer, disposed over the front side of the first semiconductor substrate;
a second interlayer dielectric layer, disposed over the first interlayer dielectric layer; and
a source/drain contact via, extending through the first interlayer dielectric layer and the second interlayer dielectric layer, wherein the source/drain contact via is electrically connected with the transistor;
a through-substrate via, extending from the back side of the first semiconductor substrate to beyond the front side of the first semiconductor substrate, wherein a depth of the through-substrate via beyond the front side of the first semiconductor substrate is less than or equal to a thickness of the first interlayer dielectric layer.

17. The image sensor device of claim 16, further comprises:
a second semiconductor substrate, overlapping with the first semiconductor substrate; and
a photodiode, disposed in a pixel area of the second semiconductor substrate and electrically connected with the transistor, wherein the through-substrate via is overlapping with the pixel area.

18. The image sensor device of claim 16, further comprises:
an interlayer conductive layer, located between the first interlayer dielectric layer and the second interlayer dielectric layer, wherein the through-substrate via is extending into the first interlayer dielectric layer and in contact with the interlayer conductive layer.

19. The image sensor device of claim 16, further comprises:
a conductive pad, located between the first interlayer dielectric layer and the first semiconductor substrate;
an insulation structure, located between the conductive pad and the first semiconductor substrate, wherein a sidewall of the insulation structure is aligned with a sidewall of the conductive pad, and the through-substrate via is penetrating through the insulation structure and in contact with the conductive pad.

20. The image sensor device of claim 16, wherein the through-substrate via comprises:
a first conductive plug, extending from a top surface of the first interlayer dielectric layer into the first semiconductor substrate; and
a second conductive plug, extending from the back side of the first semiconductor substrate into the first semiconductor substrate, and electrically connected with the first conductive plug.
